(19) United States
(12) Patent Application Publication
(10) Pub. No.: US 2026/0181797 A1
(43) Pub. Date: Jun. 25, 2026

(54) ELECTRONIC DEVICE

(71) Applicant: Samsung Display Co., LTD., Yongin-si (KR)

(72) Inventors: Gana Kim, Yongin-si (KR); Jangyeol Yoon, Yongin-si (KR); Jinwoo Choi, Yongin-si (KR)

(21) Appl. No.: 19/293,608

(22) Filed: Aug. 7, 2025

(30) Foreign Application Priority Data
Dec. 24, 2024 (KR) 10-2024-0196213

(51) Int. Cl. H05K 5/02; H10H 29/85

(52) U.S. Cl. CPC H05K 5/0217; H10H 29/8506

(57) ABSTRACT

Provided is an electronic device including a display apparatus which is stretchable and a pressing unit that is fixed to the display apparatus and applies a force to the display apparatus, wherein the pressing unit includes: a frame portion; a plate portion arranged on the frame portion and having magnetism; and a stroke module arranged between the frame portion and the plate portion and which moves in a first direction and a second direction crossing the first direction with respect to the frame portion, and the stroke module includes a stroke unit which is switched between a first state with magnetism and a second state with no magnetism and moves in a third-1 direction toward the plate portion and a third-2 direction away from the plate portion.

This application claims priority to Korean Patent Application No. 10-2024-0196213, filed on Dec. 24, 2024, and all the benefits accruing therefrom under 35 U.S.C. § 119, the content of which in its entirety is herein incorporated by reference.

### BACKGROUND

### Field

Embodiments of the present disclosure relate to an electronic device, for example, an electronic device including a flexible display apparatus.

### Description of the Related Art

As display apparatuses that visually display electrical signals have been developed, various display apparatuses with excellent characteristics such as, for example, thinness, light weight, and low power consumption have been introduced. For example, flexible display apparatuses that may be folded or rolled into the shape of a roll have been introduced. Recently, research and development have been actively conducted on display apparatuses having various structures, such as, for example, stretchable display apparatuses that may be changed into various forms.

### SUMMARY

### Disclosure of Invention

### Technical Problem

Embodiments of the present disclosure provide a display apparatus, for example, a flexible display apparatus.

### Solution to Problem

In an embodiment of the present disclosure, disclosed is an electronic device including a display apparatus which is stretchable and a pressing unit that is fixed to the display apparatus and applies a force to the display apparatus, wherein the pressing unit includes: a frame portion; a plate portion arranged on the frame portion and having magnetism; and a stroke module arranged between the frame portion and the plate portion and which moves in a first direction and a second direction crossing the first direction with respect to the frame portion, and the stroke module includes a stroke unit which is switched between a first state with magnetism and a second state with no magnetism and moves in a third-1 direction toward the plate portion and a third-2 direction away from the plate portion.

In an embodiment, the stroke unit may apply the force to the plate portion in the first state.

In an embodiment, the stroke unit may apply the force to the plate portion in the third-1 direction, and at least a portion of the display apparatus may be elongated in the third-1 direction based on the force.

In an embodiment, the stroke unit may apply the force to the plate portion in the third-2 direction, and at least a portion of the display apparatus may be elongated in the third-2 direction based on the force.

In an embodiment, the stroke unit may be switched from the first state to the second state and may move in the third-2 direction such that the stroke unit is spaced apart from the plate portion.

In an embodiment, the stroke unit may include: a body portion; and a roller portion connected to the body portion in the third-1 direction and which freely rotates with respect to the body portion.

In an embodiment, in a state where the pressing unit applies the force to the display apparatus, the stroke module may move in at least one of the first direction and the second direction with respect to the frame portion, such that the roller portion rotates.

In an embodiment, the stroke module may be provided as a plurality of stroke modules, and the plurality of stroke modules may move independently from one another.

In an embodiment, the plurality of stroke modules may apply respective forces to the plate portion at different respective positions of the plate portion.

In an embodiment, the stroke unit may include at least one of an electromagnet and an electropermanent magnet.

In an embodiment of the present disclosure, disclosed is an electronic device including a display apparatus which is stretchable and a pressing unit that is fixed to the display apparatus and applies a force to the display apparatus, wherein the pressing unit includes: a frame portion; a plate portion arranged on the frame portion and having magnetism; and a stroke module that is arranged between the frame portion and the plate portion, moves in a first direction and a second direction crossing the first direction with respect to the frame portion, and applies a force to the plate portion, and the plate portion includes a first area and a plurality of second areas having elongations different from an elongation of the first area.

In an embodiment, the stroke module may include a stroke unit which is switched between a first state with magnetism and a second state with no magnetism and moves in a third-1 direction toward the plate portion and a third-2 direction away from the plate portion.

In an embodiment, the stroke unit may apply the force to the plate portion in the first state, at a position where the stroke module overlaps any one of the plurality of second areas.

In an embodiment, the stroke unit may apply the force to the plate portion in the third-1 direction, and at least a portion of the display apparatus may be elongated in the third-1 direction based on the force.

In an embodiment, the stroke unit may apply the force to the plate portion in the third-2 direction, and at least a portion of the display apparatus may be elongated in the third-2 direction based on the force.

In an embodiment, the stroke unit may be switched from the first state to the second state and may move in the third-2 direction such that the stroke unit is spaced apart from the plate portion.

In an embodiment, the stroke unit may include: a body portion; and a roller portion connected to the body portion in the third-1 direction and which freely rotates with respect to the body portion.

In an embodiment, in a state where the pressing unit applies the force to the display apparatus, the stroke module may move in at least one of the first direction and the second direction with respect to the frame portion, such that the roller portion rotates.

In an embodiment, the stroke unit may include at least one of an electromagnet and an electropermanent magnet.

In an embodiment, the stroke module may be provided as a plurality of stroke modules, and the plurality of stroke modules may move independently from one another and may apply respective forces to the plate portion at different respective positions of the plate portion.

Other aspects, features, and advantages other than those described herein will become apparent from the following drawings, claims, and detailed description of the disclosure.

### Advantageous Effects of Invention

According to an embodiment of the present disclosure, a display apparatus in which damage due to concentration of stress can be prevented and which is stretchable in various directions may be provided. These effects are examples, and the scope of the present disclosure is not limited to the above-described effects.

### BRIEF DESCRIPTION OF THE DRAWINGS

FIG. 1 is a perspective view schematically illustrating a display apparatus according to an embodiment of the present disclosure.

FIGS. 2A and 2B are perspective views illustrating states where the display apparatus of FIG. 1 is stretched in a first direction.

FIG. 2C is a perspective view illustrating a state where the display apparatus of FIG. 1 is stretched in a second direction.

FIG. 2D is a perspective view illustrating a state where the display apparatus of FIG. 1 is stretched in the first direction and the second direction.

FIG. 2E is a perspective view illustrating a state where the display apparatus of FIG. 1 is stretched in a third direction.

FIG. 3 is a plan view schematically illustrating a display apparatus according to an embodiment of the present disclosure.

FIG. 4A is an enlarged plan view of a portion IV of FIG. 3 as a portion of a display apparatus according to an embodiment of the present disclosure.

FIG. 4B is an enlarged plan view of the portion IV of FIG. 3 as a portion of a display apparatus according to an embodiment of the present disclosure.

FIG. 4C is an enlarged plan view of the portion IV of FIG. 3 as a portion of a display apparatus according to an embodiment of the present disclosure.

FIG. 5 is a cross-sectional view schematically illustrating a first island portion and a first bridge portion, which are arranged in a display area of a display apparatus, according to an embodiment of the present disclosure.

FIGS. 6A to 6C are each an equivalent circuit diagram of a sub-pixel of a display apparatus according to an embodiment of the present disclosure.

FIG. 7A is a cross-sectional view schematically illustrating a light-emitting element of a display apparatus according to an embodiment of the present disclosure.

FIG. 7B is a cross-sectional view schematically illustrating a light-emitting element of a display apparatus according to an embodiment of the present disclosure.

FIGS. 8A and 8B are perspective views schematically illustrating an electronic device according to an embodiment of the present disclosure.

FIG. 9 is an exploded perspective view schematically illustrating a pressing unit according to an embodiment of the present disclosure.

FIG. 10A is a cross-sectional view schematically illustrating a pressing unit according to an embodiment of the present disclosure.

FIG. 10B is a plan view schematically illustrating a pressing unit according to an embodiment of the present disclosure.

FIG. 10C is a cross-sectional view schematically illustrating a pressing unit according to an embodiment of the present disclosure.

FIG. 10D is a plan view schematically illustrating a pressing unit according to an embodiment of the present disclosure.

FIGS. 10E to 10I are cross-sectional views schematically illustrating a pressing unit according to an embodiment of the present disclosure.

FIG. 11A is a cross-sectional view schematically illustrating a pressing unit according to an embodiment of the present disclosure.

FIG. 11B is a cross-sectional view schematically illustrating a pressing unit according to an embodiment of the present disclosure.

FIG. 12 is an exploded perspective view schematically illustrating a pressing unit according to an embodiment of the present disclosure.

FIG. 13A is a cross-sectional view schematically illustrating a pressing unit according to an embodiment of the present disclosure.

FIG. 13B is a plan view schematically illustrating a pressing unit according to an embodiment of the present disclosure.

FIG. 13C is a cross-sectional view schematically illustrating a pressing unit according to an embodiment of the present disclosure.

FIG. 13D is a plan view schematically illustrating a pressing unit according to an embodiment of the present disclosure.

FIGS. 13E to 13H are cross-sectional views schematically illustrating a pressing unit according to an embodiment of the present disclosure.

FIG. 14A is a perspective view schematically illustrating an electronic device including a display apparatus according to an embodiment of the present disclosure.

FIG. 14B is a block diagram schematically illustrating an electronic device including a display apparatus according to an embodiment of the present disclosure.

FIGS. 15A to 15D are each a perspective view schematically illustrating embodiments of an electronic device including a display apparatus according to an embodiment of the present disclosure.

FIGS. 16A to 16E are each a perspective view schematically illustrating an electronic device according to an embodiment of the present disclosure.

### DETAILED DESCRIPTION

### Mode for the Invention

The present disclosure may undergo various modifications and have various embodiments, and particular embodiments will be illustrated in the drawings and described in the detailed description section. The effect and features of the present disclosure, and a method to achieve the same, will be clearer referring to the embodiments described in detail below with the drawings. However, the present disclosure may be implemented in various forms, not by being limited to the embodiments presented below.

Hereinafter, embodiments of the present disclosure will be described in detail with reference to the accompanying drawings, and in the description with reference to the drawings, the same or corresponding components are indicated by the same reference numerals, and redundant descriptions thereof are omitted.

In the following embodiment, the terms “first,” “second,” and the like are not used in a restrictive sense but are used to distinguish one component from another.

In the following embodiment, the expression of singularity includes the expression of plurality unless clearly specified otherwise in context.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

In the following embodiment, the term “include” or “have” means that a feature or component described in the specification is present, and does not preclude the possibility that one or more other features or components may be added.

In the following embodiment, when a layer, area, or component is referred to as being above or on another layer, area, or component, it may include not only a case where the layer, area, or component is directly on the other layer, area, or component, but also a case where intervening layers, areas, or components may be present.

Sizes of components in the drawings may be exaggerated or reduced for convenience of explanation. For example, because sizes and thicknesses of components in the drawings are arbitrarily illustrated for convenience of explanation, the present disclosure is not necessarily limited to what is illustrated.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or may be performed in an order opposite to the described order.

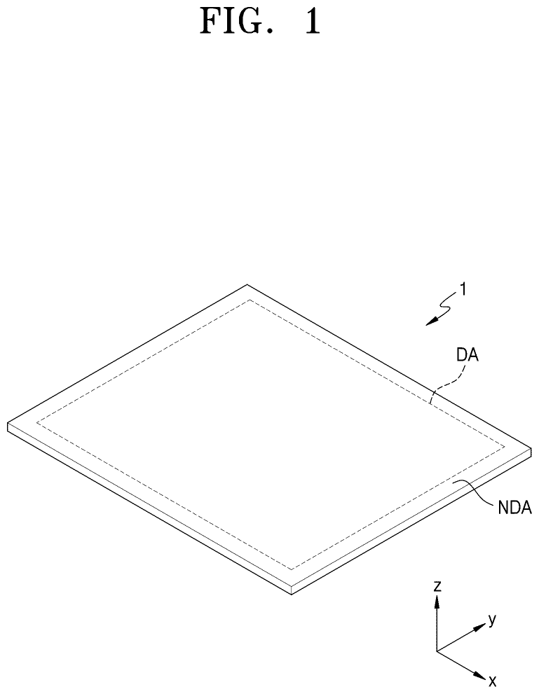

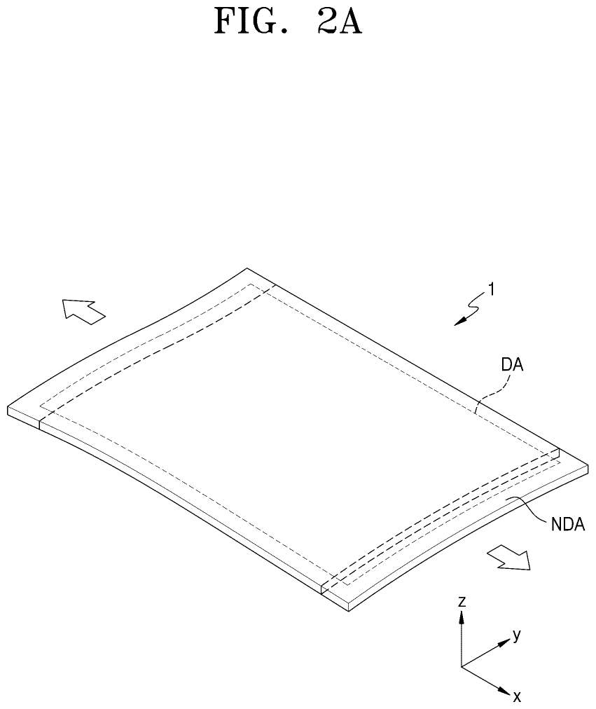

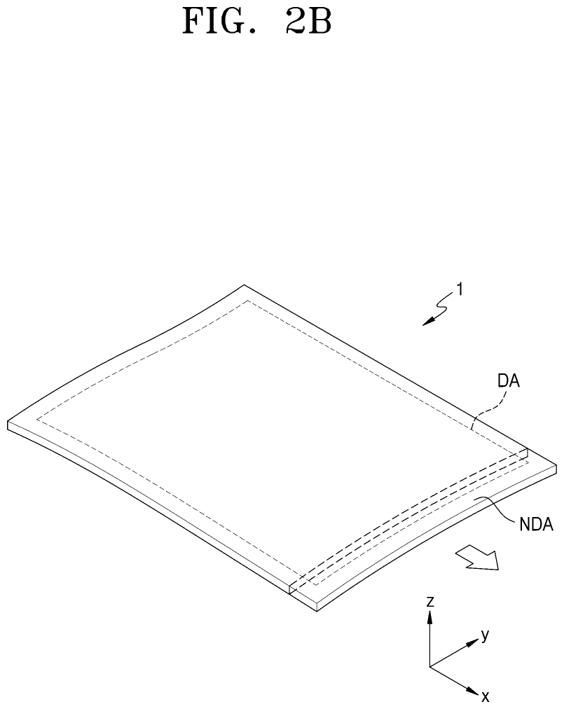

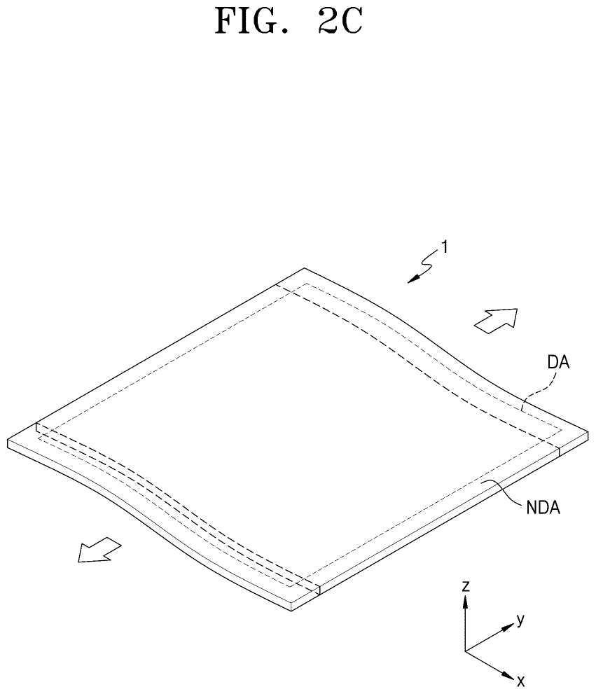

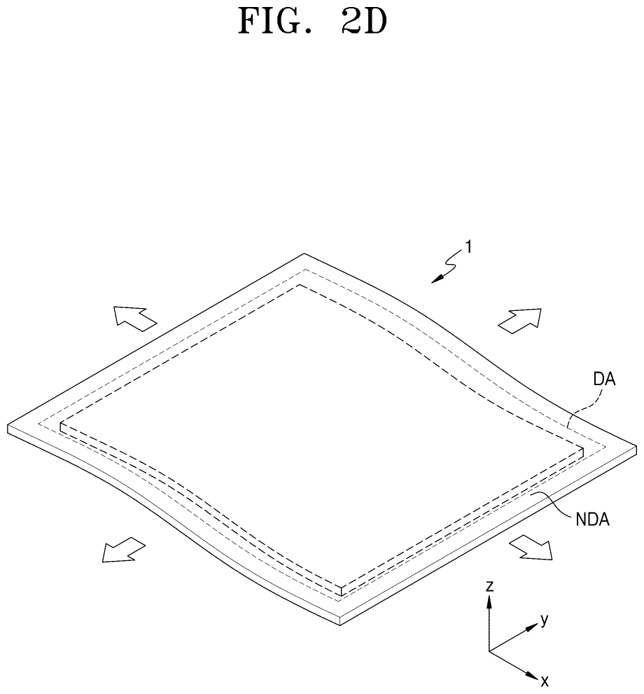

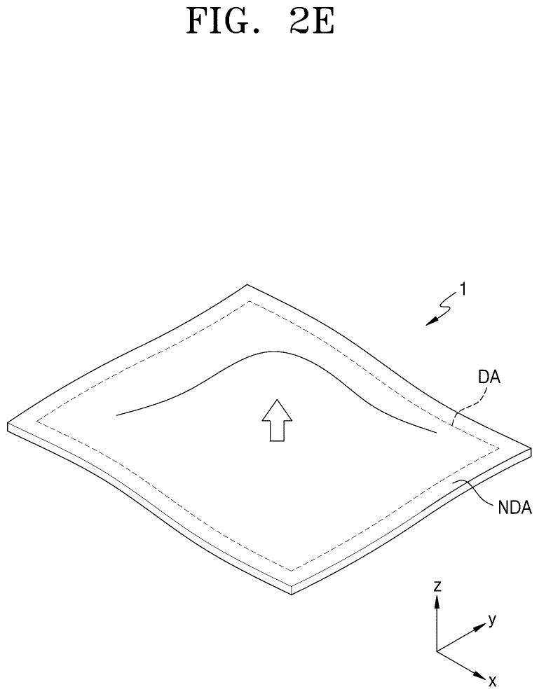

FIG. 1 is a perspective view schematically illustrating a display apparatus 1 according to an embodiment of the present disclosure. FIGS. 2A and 2B are perspective views illustrating states where the display apparatus 1 of FIG. 1 is stretched in a first direction. FIG. 2C is a perspective view illustrating a state where the display apparatus 1 of FIG. 1 is stretched in a second direction. FIG. 2D is a perspective view illustrating a state where the display apparatus 1 of FIG. 1 is stretched in the first direction and the second direction. FIG. 2E is a perspective view illustrating a state where the display apparatus 1 of FIG. 1 is stretched in a third direction.

Referring to FIG. 1, the display apparatus 1 may include a display area DA and a non-display area NDA. The display area DA may include a plurality of pixels. The display apparatus 1 may provide a certain image by using light emitted from the plurality of pixels. The non-display area NDA may be arranged outside the display area DA. The non-display area NDA may be an area where pixels are not arranged, and may entirely surround the display area DA.

The display apparatus 1 may be stretched or shrunk in various directions. The display apparatus 1 may be stretched in a first direction (for example, an x direction and/or a −x direction) due to an external force applied by an external object or a user. In an embodiment, as illustrated in FIGS. 2A and 2B, the display area DA and/or the non-display area NDA of the display apparatus 1 may be stretched in the first direction (for example, the x direction and/or the −x direction). For example, as illustrated in FIG. 2A, the display apparatus 1 may be stretched in the x direction and the −x direction, or, as illustrated in FIG. 2B, the display apparatus 1 may be stretched in the x direction while one side of the display apparatus 1 is fixed.

The display apparatus 1 may be stretched in a second direction (for example, a y direction and/or a −y direction) due to an external force applied by an external object or a user. In an embodiment, as illustrated in FIG. 2C, the display area DA and/or the non-display area NDA of the display apparatus 1 may be stretched in the y direction and the −y direction. In another embodiment, the display apparatus 1 may be stretched in the y direction or the −y direction while one side of the display apparatus 1 is fixed.

The display apparatus 1 may be stretched in a plurality of directions, for example, in the first direction (for example, the x direction and/or the −x direction) and the second direction (for example, the y direction and/or the −y direction), due to an external force applied by an external object or a part of a human body. As illustrated in FIG. 2D, the display area DA and/or the non-display area NDA of the display apparatus 1 may be stretched in the ±x direction and the ±y direction.

The display apparatus 1 may be stretched in a third direction (for example, a z direction or a −z direction) due to an external force applied by an external object or a part of a human body. In an embodiment, FIG. 2E illustrates that a portion of the display apparatus 1, for example, a partial area of the display area DA, protrudes in the z direction. In another embodiment, a portion of the display apparatus 1, for example, a partial area of the display area DA, may protrude in the −z direction (or be recessed in the z direction).

FIGS. 2A to 2E illustrate the display apparatus 1 that is stretched in the first direction, the second direction, and/or the third direction, but embodiments of the present disclosure are not limited thereto. In another embodiment, the display apparatus 1 may be changed into various irregular shapes, such as, for example, being bent or twisted along two or more axes.

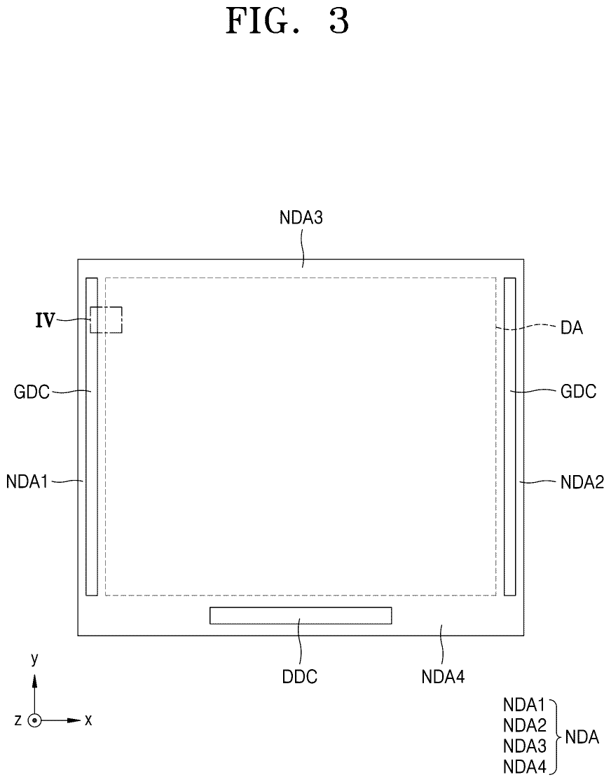

FIG. 3 is a plan view schematically illustrating the display apparatus 1 according to an embodiment of the present disclosure.

A plurality of pixels may be arranged in the display area DA of the display apparatus 1. Each of the pixels may include sub-pixels that emit light of different colors. Light-emitting elements respectively corresponding to the sub-pixels may be arranged in the display area DA. A circuit for providing electrical signals to the light-emitting elements arranged in the display area DA and transistors electrically connected to the light-emitting elements may be arranged in the non-display area NDA around the display area DA. A gate driving circuit GDC may be arranged in each of a first non-display area NDA1 and a second non-display area NDA2, which are arranged at opposite sides of the display area DA. The gate driving circuit GDC may include drivers for providing electrical signals to a gate electrode of each of the transistors electrically connected to the light-emitting elements. FIG. 3 illustrates that the gate driving circuit GDC is arranged in each of the first non-display area NDA1 and the second non-display area NDA2, but embodiments of the present disclosure are not limited thereto. In another embodiment, the gate driving circuit GDC may be arranged in any one of the first non-display area NDA1 and the second non-display area NDA2.

A data driving circuit DDC may be arranged in a third non-display area NDA3 and/or a fourth non-display area NDA4, which connect(s) the first non-display area NDA1 and the second non-display area NDA2 to each other. In an embodiment, FIG. 3 illustrates that the data driving circuit DDC is arranged in the fourth non-display area NDA4. In another embodiment, the data driving circuit DDC may be arranged in each of the third non-display area NDA3 and the fourth non-display area NDA4.

FIG. 3 illustrates that the data driving circuit DDC is arranged in the fourth non-display area NDA4 of the display apparatus 1, but the present disclosures is not limited thereto. In another embodiment, the display apparatus 1 may further include a flexible circuit board (not illustrated) electrically connected to the fourth non-display area NDA4 via a terminal portion (not illustrated) arranged in the fourth non-display area NDA4, and the data driving circuit DDC may be arranged on the flexible circuit board.

In some embodiments, the elongation of the non-display area NDA may be less than or equal to the elongation of the display area DA. In an embodiment, the elongation of the non-display area NDA may vary from area to area. For example, the first non-display area NDA1, the second non-display area NDA2, and the third non-display area NDA3 may have substantially the same elongation, while the elongation of the fourth non-display area NDA4 may be less than the elongation of each of the first non-display area NDA1, the second non-display area NDA2, and the third non-display area NDA3. The elongation in the present specification refers to a value representing a change in length (ΔL/L) by which the display apparatus 1 may be stretched without physical damage to the display apparatus 1 when an external force is applied to the display apparatus 1. Herein, ΔL refers to the amount of change in length of the display apparatus, and L refers to an initial length of the display apparatus.

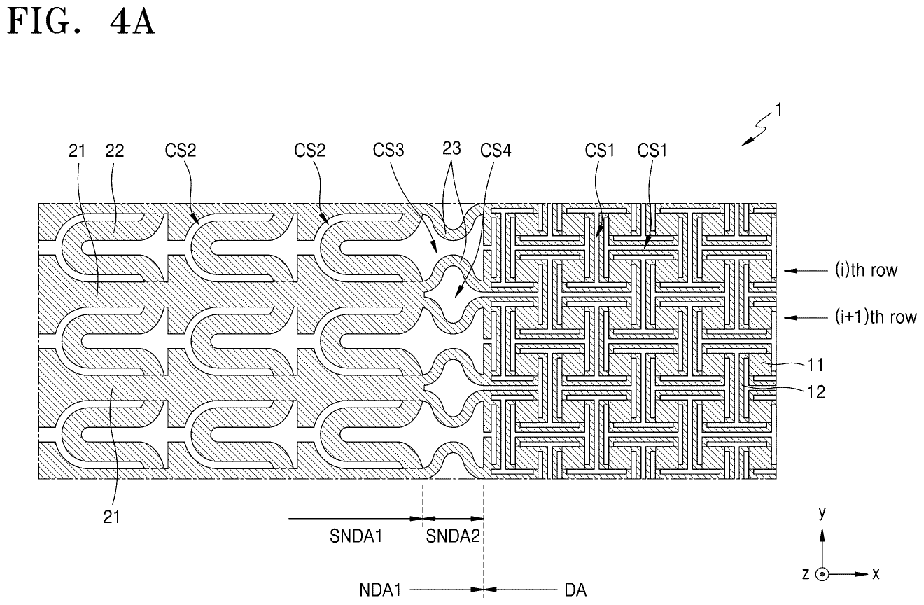

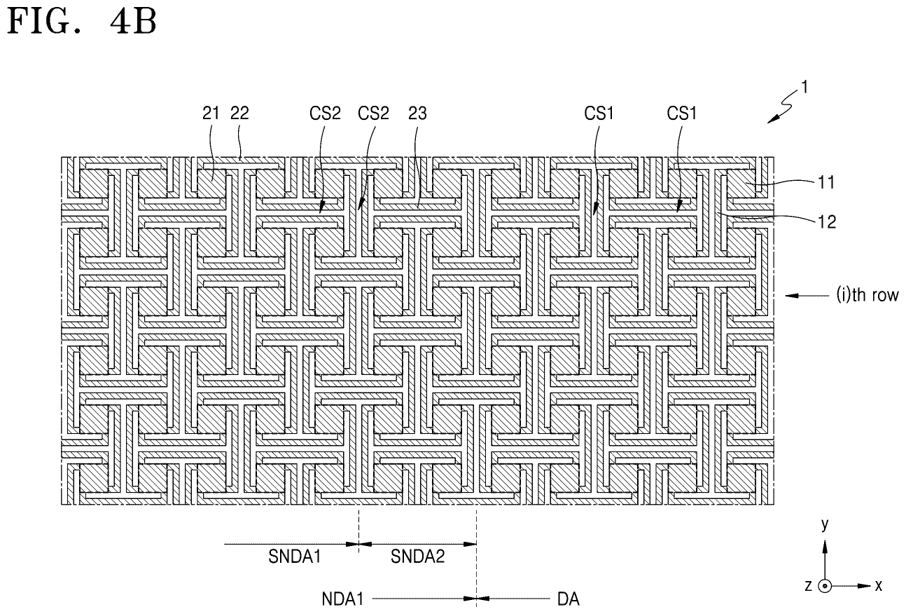

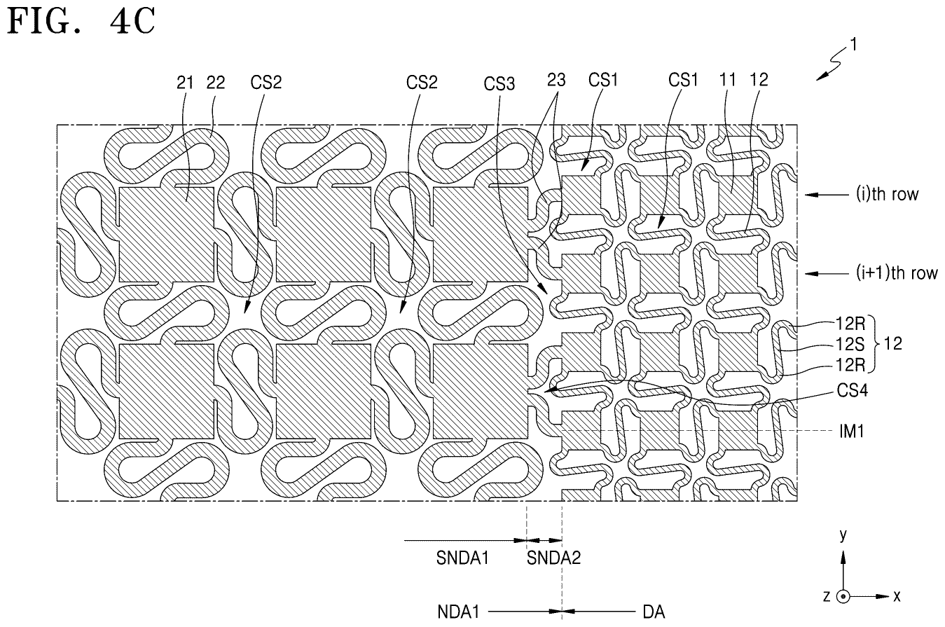

FIG. 4A is an enlarged plan view of a portion IV of FIG. 3 as a portion of the display apparatus 1 according to an embodiment of the present disclosure.

Referring to FIG. 4A, the display apparatus 1 may include, in the display area DA, first island portions 11 spaced apart from each other in the first direction (for example, the x direction or the −x direction) and the second direction (for example, the y direction or the −y direction) and first bridge portions 12 connecting adjacent first island portions 11 to each other.

Each of the first island portions 11 may be connected to a plurality of first bridge portions 12. For example, each first island portion 11 may be connected to four first bridge portions 12. Two first bridge portions 12 may be arranged at opposite sides of the first island portion 11 in the first direction (for example, the x direction or the −x direction), and the other two first bridge portions 12 may be arranged at opposite sides of the first island portion 11 in the second direction (for example, the y direction or the −y direction). In an embodiment, the four first bridge portions 12 may be respectively connected to four sides of the first island portion 11. Each of the four first bridge portions 12 may be adjacent to each of corners of the first island portion 11.

The first bridge portions 12 may be spaced apart from each other by a first opening CS1 arranged between the first bridge portions 12. In an embodiment, a first opening CS1 having a substantially H shape and a first opening CS1 having a substantially I shape obtained by rotating the H shape by 90 degrees may be alternately and repeatedly arranged in the first direction (for example, the x direction or the −x direction) and the second direction (for example, the y direction or the −y direction). Both ends of each of the first bridge portions 12 may be respectively connected to adjacent first island portions 11, and one side of each first bridge portion 12 may be spaced apart from one side of the adjacent first island portion 11 and/or one side of another first bridge portion 12 by the first opening CS1.

The display apparatus 1 may include second island portions 21 spaced apart from each other and second bridge portions 22 connecting adjacent second island portions 21 to each other, in the non-display area, for example, the first non-display area NDA1 illustrated in FIG. 4A.

Each of the second island portions 21 may extend in the first direction (for example, the x direction or the −x direction). The second island portions 21 may be spaced apart from each other in the second direction (for example, the y direction or the −y direction) crossing the first direction (for example, the x direction or the −x direction). Each second island portion 21 may include drivers of the gate driving circuit GDC (of FIG. 2) described with reference to FIG. 3.

The second bridge portion 22 may have a serpentine shape. The length of the second bridge portion 22 may be greater than a shortest distance between the second island portions 21 adjacent to each other in the second direction (for example, the y direction or the −y direction). In an embodiment, the second bridge portion 22 may have a substantially omega (Ω) shape that is convex in the first direction (for example, the x direction or the −x direction). The second bridge portions 22 may be arranged between adjacent second island portions 21 and may be spaced apart from each other.

The second bridge portions 22 between adjacent second island portions 21 may be spaced apart from each other by a second opening CS2. Between adjacent second island portions 21, the second openings CS2 and the second bridge portions 22 may be alternately arranged in the first direction (for example, the x direction or the −x direction). The second openings CS2 may have the same shape. Both ends of each of the second bridge portions 22 may be connected to adjacent second island portions 21, and one side of each second bridge portion 22 may be spaced apart from one side of the adjacent second island portion 21 and/or one side of another second bridge portion 22 by the second opening CS2.

Any one second island portion 21 arranged in the first non-display area NDA1 may correspond to the first island portions 11 of a plurality of rows arranged in the display area DA. For example, any one second island portion 21 arranged in the first non-display area NDA1 may correspond to the first island portions 11 arranged in an (i)^{th} row and the first island portions 11 arranged in an (i+1)^{th} row in the display area DA (where i is a positive number greater than 0). FIG. 4A illustrates that one second island portion 21 corresponds to the first island portions 11 arranged in two rows, but embodiments of the present disclosure are not limited thereto. In another embodiment, any one second island portion 21 arranged in the first non-display area NDA1 may correspond to the first island portions 11 arranged in n rows in the display area DA (where n is a positive number of 3 or more).

The non-display area, for example, the first non-display area NDA1, may include a first sub-non-display area SNDA1 in which the second island portions 21 and the second bridge portions 22 are arranged, and a second sub-non-display area SNDA2 between the first sub-non-display area SNDA1 and the display area DA. Third bridge portions 23 for connecting the display area DA and the first sub-non-display area SNDA1 to each other may be arranged in the second sub-non-display area SNDA2. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as illustrated in FIG. 4A, the third bridge portion 23 may have a substantially omega (Ω) shape that is convex in the second direction (for example, the y direction or the −y direction). Adjacent third bridge portions 23 arranged in the second direction (for example, the y direction or the −y direction) may have a symmetrical structure in which one of the adjacent third bridge portions 23 is convex in the y direction and the other is convex in the −y direction. A third opening CS3 and a fourth opening CS4, which have different shapes from each other, may be repeated between the third bridge portions 23. The width of the third bridge portion 23 may be different from the width of the first bridge portion 12 and the width of the second bridge portion 22. In an embodiment, the width of the third bridge portion 23 may be greater than the width of the first bridge portion 12 and may be less than the width of the second bridge portion 22.

FIG. 4A illustrates that the second island portion 21 and the second bridge portion 22 of the non-display area, for example, the first non-display area NDA1, have different shapes from the first island portion 11 and the first bridge portion 12 of the display area DA, respectively. In another embodiment of the present disclosure, the second island portion 21 and the second bridge portion 22 of the non-display area may have the same shape as the first island portion 11 and the first bridge portion 12 of the display area DA, respectively.

FIG. 4B is an enlarged plan view of the portion IV of FIG. 3 as a portion of the display apparatus 1 according to an embodiment of the present disclosure.

Referring to FIG. 4B, the display apparatus 1 may include, in the display area DA, the first island portions 11 spaced apart from each other and the first bridge portions 12 spaced apart from each other by the first opening CS1 and connecting adjacent first island portions 11 to each other. The structure of the display area DA of FIG. 4B may be the same as the structure of the display area DA described with reference to FIG. 4A.

The display apparatus 1 may include the second island portions 21 and the second bridge portions 22, which are arranged in the non-display area, for example, the first non-display area NDA1. In an embodiment, the second island portions 21 and the second bridge portions 22 may have substantially the same shape as the first island portions 11 and the first bridge portions 12, respectively.

The second island portions 21 may be spaced apart from each other in the first direction (for example, the x direction or the −x direction) and the second direction (for example, the y direction or the −y direction) in the non-display area, for example, the first non-display area NDA1. Each of the second bridge portions 22 may connect adjacent second island portions 21 to each other. The second bridge portions 22 may be spaced apart from each other by the second opening CS2 arranged between the second bridge portions 22.

The second opening CS2 may have substantially the same shape as the first opening CS1. For example, the second opening CS2 having a substantially H shape and the second opening CS2 having a substantially I shape may be alternately and repeatedly arranged in the non-display area, for example, the first non-display area NDA1. Both ends of each second bridge portion 22 may be respectively connected to adjacent second island portions 21, and one side of each second bridge portion 22 may be spaced apart from one side of the adjacent second island portion 21 and/or one side of another second bridge portion 22 by the second opening CS2.

Each of the second island portions 21 may be connected to four second bridge portions 22. Each second island portion 21 may include drivers of the gate driving circuit GDC (of FIG. 2) described with reference to FIG. 3.

The second island portions 21 of any one row arranged in the first non-display area NDA1 may correspond to the first island portions 11 of any one row arranged in the display area DA. For example, the second island portions 21 arranged in an (i)^{th} row in the first direction (for example, the x direction or the −x direction) in the first non-display area NDA1 may correspond to the first island portions 11 arranged in the same row, for example, the (i)^{th} row, in the display area DA (where i is a positive number greater than 0).

The display apparatus 1 may include the third bridge portions 23 arranged in the second sub-non-display area SNDA2 for connecting the display area DA and the first sub-non-display area SNDA1 to each other. The non-display area, for example, the first non-display area NDA1, may include the first sub-non-display area SNDA1 in which the second island portions 21 and the second bridge portions 22 are arranged, and the second sub-non-display area SNDA2 including the third bridge portions 23 and arranged between the first sub-non-display area SNDA1 and the display area DA. The third bridge portion 23 may be substantially the same as the first bridge portion 12 and the second bridge portion 22. For example, the width of the third bridge portion 23 may be the same as the width of the first bridge portion 12 and the width of the second bridge portion 22.

FIG. 4C is an enlarged plan view of the portion IV of FIG. 3 as a portion of the display apparatus 1 according to an embodiment of the present disclosure.

Referring to FIG. 4C, the display apparatus 1 may include, in the display area DA, the first island portions 11 spaced apart from each other in the first direction (for example, the x direction or the −x direction) and the second direction (for example, the y direction or the −y direction) and the first bridge portions 12 connecting adjacent first island portions 11 to each other.

The first bridge portions 12 may be spaced apart from each other by the first opening CS1 arranged between the first bridge portions 12. The first bridge portion 12 may have a serpentine shape. For example, as illustrated in FIG. 4C, the first bridge portion 12 may have a substantially “alphabet S” shape including two rounded portions 12R and a straight portion 12S between the two rounded portions 12R.

Each of the first island portions 11 may be connected to a plurality of first bridge portions 12. For example, each first island portion 11 may be connected to four first bridge portions 12. Two first bridge portions 12 may be arranged at opposite sides of the first island portion 11 in the first direction (for example, the x direction or the −x direction), and the other two first bridge portions 12 may be arranged at opposite sides of the first island portion 11 in the second direction (for example, the y direction or the −y direction). The four first bridge portions 12 may be respectively connected to four sides of the first island portion 11. Each of the four first bridge portions 12 may be adjacent to each of corners of the first island portion 11.

The display apparatus 1 may include the second island portions 21 spaced apart from each other in the first direction (for example, the x direction or the −x direction) and the second direction (for example, the y direction or the −y direction) and the second bridge portions 22 connecting adjacent second island portions 21 to each other, in the non-display area, for example, the first non-display area NDA1 illustrated in FIG. 4C.

The second bridge portions 22 may be spaced apart from each other by the second opening CS2 arranged between the second bridge portions 22. The second bridge portion 22 may have a serpentine shape. For example, as illustrated in FIG. 4C, the second bridge portion 22 may have a substantially “alphabet S” shape. The size and/or width of the second bridge portion 22 may be different from the size and/or width of the first bridge portion 12. For example, the size and/or width of the second bridge portion 22 may be greater than the size and/or width of the first bridge portion 12. The radius of curvature of a rounded portion of the second bridge portion 22 may be different from the radius of curvature of a rounded portion of the first bridge portion 12. For example, the radius of curvature of the rounded portion of the second bridge portion 22 may be greater than the radius of curvature of the rounded portion of the first bridge portion 12.

Each of the second island portions 21 may be connected to a plurality of second bridge portions 22. Each second island portion 21 may be connected to four second bridge portions 22. Two second bridge portions 22 may be arranged at opposite sides of the second island portion 21 in the first direction (for example, the x direction or the −x direction), and the other two second bridge portions 22 may be arranged at opposite sides of the second island portion 21 in the second direction (for example, the y direction or the −y direction). In an embodiment, the four second bridge portions 22 may be respectively connected to four sides of the second island portion 21. Each of the second bridge portions 22 may be connected to a central portion of each of the sides of the second island portion 21.

The second island portions 21 of any one row arranged in the first non-display area NDA1 may correspond to the first island portions 11 of a plurality of rows arranged in the display area DA. For example, the second island portions 21 of any one row arranged in the first non-display area NDA1 may correspond to the first island portions 11 arranged in an (i)^{th} row and the first island portions 11 arranged in an (i+1)^{th} row in the display area DA (where i is a positive number greater than 0). In another embodiment, the second island portions 21 of any one row may correspond to the first island portions 11 arranged in n rows (where n is a positive number of 3 or more).

The non-display area, for example, the first non-display area NDA1, may include the first sub-non-display area SNDA1 in which the second island portions 21 and the second bridge portions 22 are arranged, and the second sub-non-display area SNDA2 between the first sub-non-display area SNDA1 and the display area DA. The third bridge portions 23 for connecting the display area DA and the first sub-non-display area SNDA1 to each other may be arranged in the second sub-non-display area SNDA2. One end of the third bridge portion 23 may be connected to the second island portion 21, and the other end of the third bridge portion 23 may be connected to the first island portion 11. For example, one end of the third bridge portion 23 may be connected to a central portion of one side of the second island portion 21, and the other end of the third bridge portion 23 may be connected to a central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. The third opening CS3 and the fourth opening CS4, which have different shapes from each other, may be alternately arranged between the third bridge portions 23 in the second direction (for example, the y direction or the −y direction).

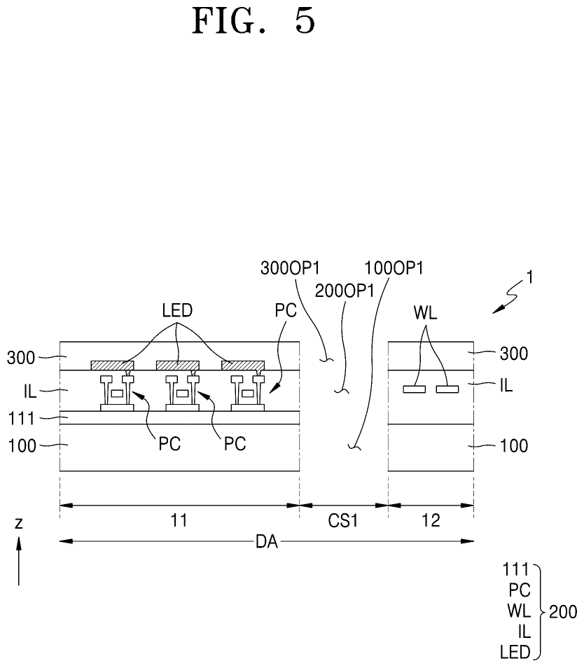

FIG. 5 is a cross-sectional view schematically illustrating the first island portion 11 and the first bridge portion 12, which are arranged in the display area DA of the display apparatus 1 according to an embodiment of the present disclosure.

Referring to FIG. 5, the first island portion 11 and the first bridge portion 12, which are arranged in the display area DA, may be spaced apart from each other with the first opening CS1 between the first island portion 11 and the first bridge portion 12. The first island portion 11 may include light-emitting elements LED and a circuit, for example, a pixel driving circuit unit PC, electrically connected to each of the light-emitting elements LED to drive each of the light-emitting elements LED, and the first bridge portion 12 may include a wiring WL electrically connected to the pixel driving circuit units PC arranged in each of adjacent first island portions 11.

Regarding the first island portion 11, a buffer layer 111 including an inorganic insulating material may be arranged on a substrate 100, and the pixel driving circuit unit PC may be arranged on the buffer layer 111. An insulating layer IL including an inorganic insulating material and/or an organic insulating material may be arranged between the pixel driving circuit unit PC and the light-emitting element LED. The light-emitting element LED may be arranged on the insulating layer IL and may be electrically connected to the corresponding pixel driving circuit unit PC. The light-emitting elements LED may emit light of different colors or light of the same color. In an embodiment, the light-emitting elements LED may respectively emit red light, green light, and blue light. In some embodiments, the light-emitting elements LED may emit white light. In another embodiment, the light-emitting elements LED may respectively emit red light, green light, blue light, and white light.

The substrate 100 may include polymer resin such as, for example, polyethersulfone, polyarylate, polyether imide, polyethylene naphthalate, polyethylene terephthalate, polyphenylene sulfide, polyimide, polycarbonate, cellulose triacetate, cellulose acetate propionate, or the like. In an embodiment, the substrate 100 may be a single layer including the polymer resin. In another embodiment, the substrate 100 may have a multilayer structure including a base layer including the polymer resin and a barrier layer including an inorganic insulating material. The substrate 100 including polymer resin may be flexible, rollable, and bendable.

In an embodiment, FIG. 5 illustrates that three pixel driving circuit units PC are arranged in each first island portion 11 and three light-emitting elements LED are respectively connected to the pixel driving circuit units PC, but embodiments of the present disclosure are not limited thereto. In another embodiment, the number of each of the pixel driving circuit units PC and the light-emitting elements LED, which are arranged in the first island portion 11, may be one, two, or four or more.

An encapsulation layer 300 may be arranged on the light-emitting element LED and may protect the light-emitting element LED from an external force and/or moisture penetration. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as, for example, resin. In some embodiments, the encapsulation layer 300 may include urethane epoxy acrylate. The encapsulation layer 300 may include a photosensitive material, for example, photoresist.

Regarding the first bridge portion 12, the insulating layer IL including an organic insulating material may be arranged on the substrate 100. The first bridge portion 12 that is relatively highly deformed when the display apparatus 1 is stretched may not include a layer including an inorganic insulating material that is prone to cracks, unlike the first island portion 11.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a different stacked structure from the substrate 100 corresponding to the first island portion 11. In some embodiments, the substrate 100 corresponding to the first bridge portion 12 may have a multilayer structure including a base layer including polymer resin and a barrier layer including an inorganic insulating material, and the substrate 100 corresponding to the first bridge portion 12 may have a structure including a polymer resin layer without a layer including an inorganic insulating material.

As described herein, the wirings WL of the first bridge portion 12 may be signal lines (for example, a gate line, a data line, or the like) for providing an electrical signal to a transistor included in the pixel driving circuit unit PC of the first island portion 11 or voltage lines (for example, a driving voltage line, an initialization line, or the like) for providing a voltage to the transistor included in the pixel driving circuit unit PC. The encapsulation layer 300 may be arranged in the first bridge portion 12. In another embodiment, the encapsulation layer 300 may not exist in the first bridge portion 12.

Referring to FIGS. 4A to 4C and 5, the substrate 100 corresponding to the first island portion 11 and the substrate 100 corresponding to the first bridge portion 12 may be connected to each other. In other words, the plan views illustrated in FIGS. 4A to 4C may be substantially the same as a plan view of the substrate 100 of FIG. 5. In other words, the substrate 100 may include an area corresponding to the first island portion 11, an area corresponding to the first bridge portion 12, and an opening 100OP1 having the same shape as the first opening CS1.

Similarly, the encapsulation layer 300 corresponding to the first island portion 11 and the encapsulation layer 300 corresponding to the first bridge portion 12 may be connected to each other. For example, the plan views illustrated in FIGS. 4A to 4C may be substantially the same as a plan view of the encapsulation layer 300. In other words, the encapsulation layer 300 may include an area corresponding to the first island portion 11, an area corresponding to the first bridge portion 12, and an opening 300OP1 having the same shape as the first opening CS1.

A circuit-light-emitting element layer 200 between the substrate 100 and the encapsulation layer 300 may include the buffer layer 111, the pixel driving circuit unit PC, the wiring WL, the insulating layer IL, and the light-emitting element LED. Similar to the substrate 100, the plan views illustrated in FIGS. 4A to 4C may be substantially the same as a plan view of the circuit-light-emitting element layer 200. In other words, the circuit-light-emitting element layer 200 may include an opening 200OP1 having the same shape as the first opening CS1.

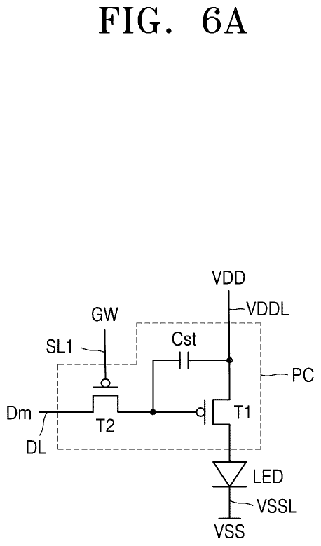

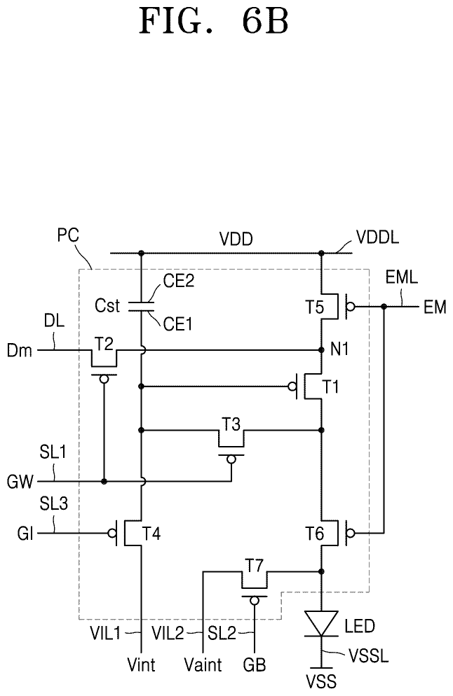

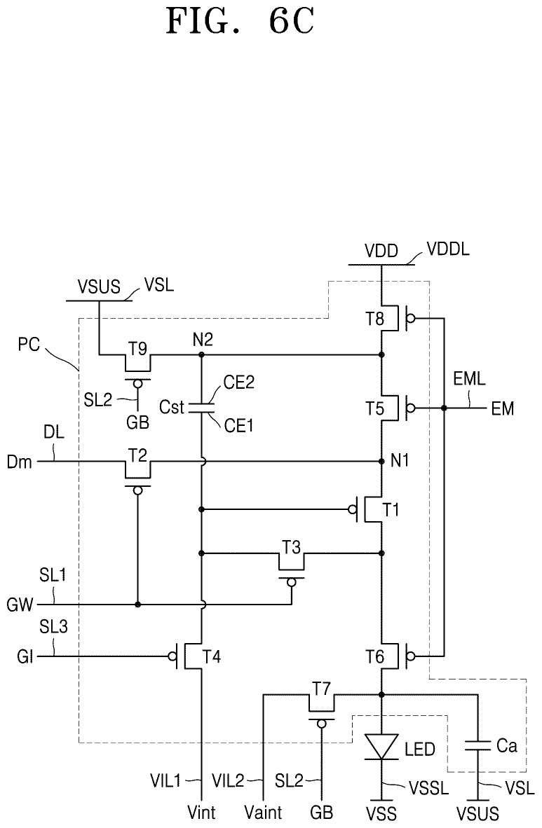

FIGS. 6A to 6C are each an equivalent circuit diagram of a sub-pixel of the display apparatus 1 according to an embodiment of the present disclosure.

Referring to FIG. 6A, the light-emitting element LED corresponding to a sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to a signal line and a voltage line. The signal line may include a gate line, such as, for example, a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit a data signal Dm input from the data line DL to the first transistor T1 according to the first scan signal GW input from the first scan line SL1.

The storage capacitor Cst may be electrically connected to the second transistor T2 and the first voltage line VDDL, and may store a voltage corresponding to a difference between a voltage received from the second transistor T2 and a first power voltage VDD supplied by the first voltage line VDDL.

The first transistor T1, as a driving transistor, may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED according to a voltage value stored in the storage capacitor Cst. The light-emitting element LED may emit light having a certain luminance according to the driving current. A first electrode of the light-emitting element LED may be electrically connected to the first transistor T1, and a second electrode of the light-emitting element LED may be electrically connected to a second voltage line VSSL that supplies a second power voltage VSS.

FIG. 6A illustrates that the pixel driving circuit unit PC includes two transistors and one storage capacitor, but in another embodiment, the pixel driving circuit unit PC may include three or more transistors.

Referring to FIG. 6B, the pixel driving circuit unit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit unit PC is electrically connected to signal lines and voltage lines. The signal lines may include a gate line, such as, for example, the first scan line SL1, a second scan line SL2, a third scan line SL3, and an emission control line EML, and the data line DL. The voltage lines may include first and second initialization voltage lines VIL1 and VIL2 and the first voltage line VDDL.

The first voltage line VDDL may transmit the first power voltage VDD to the first transistor T1. The first initialization voltage line VIL1 may transmit, to the pixel driving circuit unit PC, a first initialization voltage Vint that initializes the first transistor T1. The second initialization voltage line VIL2 may transmit, to the pixel driving circuit unit PC, a second initialization voltage Vaint that initializes the first electrode of the light-emitting element LED.

The first transistor T1 may be electrically connected to the first voltage line VDDL via the fifth transistor T5 and may be electrically connected to the light-emitting element LED via the sixth transistor T6. The first transistor T1 acts as a driving transistor and supplies a driving current to the light-emitting element LED by receiving the data signal Dm according to a switching operation of the second transistor T2.

The second transistor T2, as a data write transistor, is electrically connected to the first scan line SL1 and the data line DL. The second transistor T2 is electrically connected to the first voltage line VDDL via the fifth transistor T5. The second transistor T2 is turned on according to the first scan signal GW received via the first scan line SL1 to perform a switching operation of transmitting the data signal Dm received via the data line DL to a first node N1.

The third transistor T3 is electrically connected to the first scan line SL1 and is electrically connected to the light-emitting element LED via the sixth transistor T6. The third transistor T3 may be turned on according to the first scan signal GW received via the first scan line SL1 to diode-connect the first transistor T1.

The fourth transistor T4, as a first initialization transistor, is electrically connected to the third scan line SL3 and the first initialization voltage line VIL1. The fourth transistor T4 is turned on according to a third scan signal GI received via the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit arranged in a previous row with respect to the pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML, and are simultaneously turned on according to an emission control signal EM received via the emission control line EML to form a current path through which a driving current may flow from the first voltage line VDDL to the light-emitting element LED.

The seventh transistor T7, as a second initialization transistor, may be electrically connected to the second scan line SL2, the second initialization voltage line VIL2, and the sixth transistor T6. The seventh transistor T7 may be turned on according to a second scan signal GB received via the second scan line SL2 and may initialize the first electrode of the light-emitting element LED by transmitting the second initialization voltage Vaint from the second initialization voltage line VIL2 to the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a voltage difference between the first voltage line VDDL and the gate electrode of the first transistor T1.

Referring to FIG. 6C, the pixel driving circuit unit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit unit PC is electrically connected to signal lines and voltage lines. The signal lines may include a gate line, such as, for example, the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transmit the first power voltage VDD to the first transistor T1. The first initialization voltage line VIL1 may transmit, to the pixel driving circuit unit PC, the first initialization voltage Vint that initializes the first transistor T1. The second initialization voltage line VIL2 may transmit, to the pixel driving circuit unit PC, the second initialization voltage Vaint that initializes the first electrode of the light-emitting element LED. The sustain voltage line VSL may provide a sustain voltage VSUS to a second node N2, for example, the second electrode CE2 of the storage capacitor Cst, in an initialization period and a data write period.

The first transistor T1 may be electrically connected to the first voltage line VDDL via the fifth transistor T5 and the eighth transistor T8 and may be electrically connected to the light-emitting element LED via the sixth transistor T6. The first transistor T1 acts as a driving transistor and may supply a driving current to the light-emitting element LED by receiving the data signal Dm according to a switching operation of the second transistor T2.

The second transistor T2 is electrically connected to the first scan line SL1 and the data line DL and is electrically connected to the first voltage line VDDL via the fifth transistor T5 and the eighth transistor T8. The second transistor T2 is turned on according to the first scan signal GW received via the first scan line SL1 to perform a switching operation of transmitting the data signal Dm received via the data line DL to the first node N1.

The third transistor T3 is electrically connected to the first scan line SL1 and is electrically connected to the light-emitting element LED via the sixth transistor T6. The third transistor T3 may be turned on according to the first scan signal GW received via the first scan line SL1 to diode-connect the first transistor T1 and compensate for a threshold voltage of the first transistor T1.

The fourth transistor T4 is electrically connected to the third scan line SL3 and the first initialization voltage line VIL1, and is turned on according to the third scan signal GI received via the third scan line SL3 to initialize a voltage of the gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit arranged in a previous row with respect to the pixel driving circuit unit PC.

The fifth transistor T5, the sixth transistor T6, and the eighth transistor T8 are electrically connected to the emission control line EML, and are simultaneously turned on according to the emission control signal EM received via the emission control line EML to form a current path through which a driving current may flow from the first voltage line VDDL to the light-emitting element LED.

The seventh transistor T7, as a second initialization transistor, may be electrically connected to the second scan line SL2, the second initialization voltage line VIL2, and the sixth transistor T6. The seventh transistor T7 is turned on according to the second scan signal GB received via the second scan line SL2 to initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on according to the second scan signal GB received via the second scan line SL2, and may transmit the sustain voltage VSUS to the second node N2, for example, the second electrode CE2 of the storage capacitor Cst, in the initialization period and the data write period.

Each of the eighth transistor T8 and the ninth transistor T9 may be electrically connected to the second node N2, for example, the second electrode CE2 of the storage capacitor Cst. In some embodiments, the eighth transistor T8 may be turned off and the ninth transistor T9 may be turned on in the initialization period and the data write period, and the eighth transistor T8 may be turned on and the ninth transistor T9 may be turned off in an emission period. Because the sustain voltage VSUS is transmitted to the second node N2 in the initialization period and the data write period, the uniformity (for example, long-range uniformity (LRU)) of luminance of the display apparatus according to a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to a voltage difference between the first electrode of the light-emitting element LED and the sustain voltage line VSL while the seventh transistor T7 and the ninth transistor T9 are turned on, thereby preventing an increase in black luminance when the sixth transistor T6 is turned off.

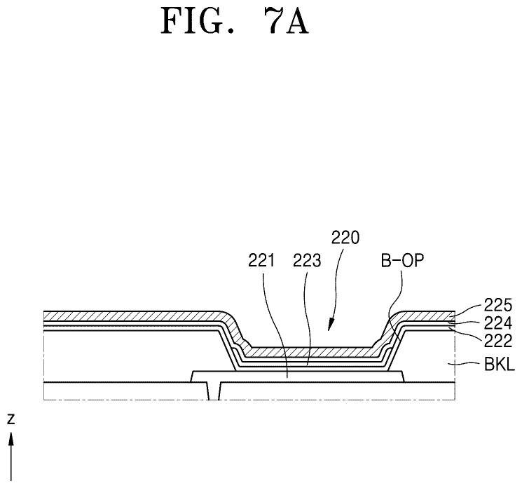

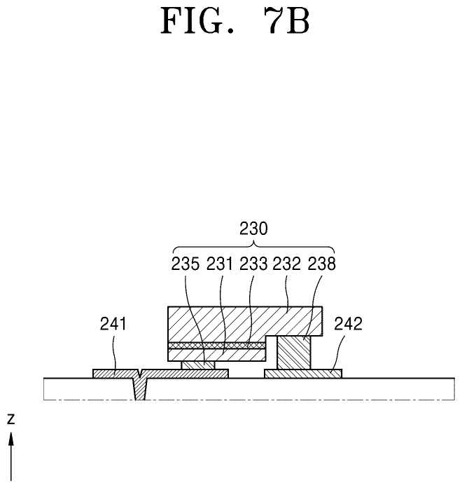

FIG. 7A is a cross-sectional view schematically illustrating a light-emitting element of a display apparatus according to an embodiment of the present disclosure.

Referring to FIG. 7A, the light-emitting element according to an embodiment of the present disclosure may include an organic light-emitting diode 220 including an organic material. The organic light-emitting diode 220 may include a first electrode 221 arranged on an insulating layer, a second electrode 225 facing the first electrode 221, and an emission layer 223 arranged between the first electrode 221 and the second electrode 225. A first function layer 222 may be arranged between the first electrode 221 and the emission layer 223, and a second functional layer 224 may be arranged between the emission layer 223 and the second electrode 225.

An edge of the first electrode 221 may be covered by a bank layer BKL including an insulating material. The bank layer BKL may include an opening B-OP overlapping a central portion of the first electrode 221.

The first electrode 221 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the first electrode 221 may further include a layer formed of ITO, IZO, ZnO, AZO, or In₂O₃ over/under the reflective layer.

The emission layer 223 may include a polymer or low-molecular-weight organic material that emits light of a certain color. The first function layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 225 may further include a layer formed of ITO, IZO, ZnO, AZO, or In₂O₃ on the (semi-)transparent layer including the above-described material.

FIG. 7B is a cross-sectional view schematically illustrating a light-emitting element of a display apparatus according to an embodiment of the present disclosure.

Referring to FIG. 7B, the light-emitting element according to an embodiment of the present disclosure may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242, which are arranged on the same layer.

In some embodiments, the first semiconductor layer 231 may include a p-type semiconductor layer. The p-type semiconductor layer may be formed of a semiconductor material having a composition formula of InₓAl_{y}Ga_{1-x-y}N (0≤x≤1, 0≤y≤1, 0≤x+y≤1), selected from among, for example, GaN, AlN, AlGaN, InGaN, InN, InAlGaN, and AlInN, and may be doped with a p-type dopant such as, for example, Mg, Zn, Ca, Sr, or Ba.

The second semiconductor layer 232 may include, for example, an n-type semiconductor layer. The n-type semiconductor layer may be formed of a semiconductor material having a composition formula of InₓAl_{y}Ga_{1-x-y}N (0≤x≤1, 0≤y≤1, 0≤x+y≤1), selected from among, for example, GaN, AlN, AlGaN, InGaN, InN, InAlGaN, and AlInN, and may be doped with an n-type dopant such as, for example, Si, Ge, or Sn.

The intermediate layer 233 may be an area where electrons and hole recombine to transition to a lower energy level and generate light having a corresponding wavelength. The intermediate layer 233 may include, for example, a semiconductor material having a composition formula of InₓAl_{y}Ga_{1-x-y}N (0≤x≤1, 0≤y≤1, 0≤x+y≤1), and may have a single or multi-quantum well (MQW) structure. In some aspects, the intermediate layer 233 may have a quantum wire structure or a quantum dot structure.

FIG. 7B illustrates that the first semiconductor layer 231 includes the p-type semiconductor layer and the second semiconductor layer 232 includes the n-type semiconductor layer, but embodiments of the present disclosure are not limited thereto. In another embodiment, the first semiconductor layer 231 may include an n-type semiconductor layer, and the second semiconductor layer 232 may include a p-type semiconductor layer.

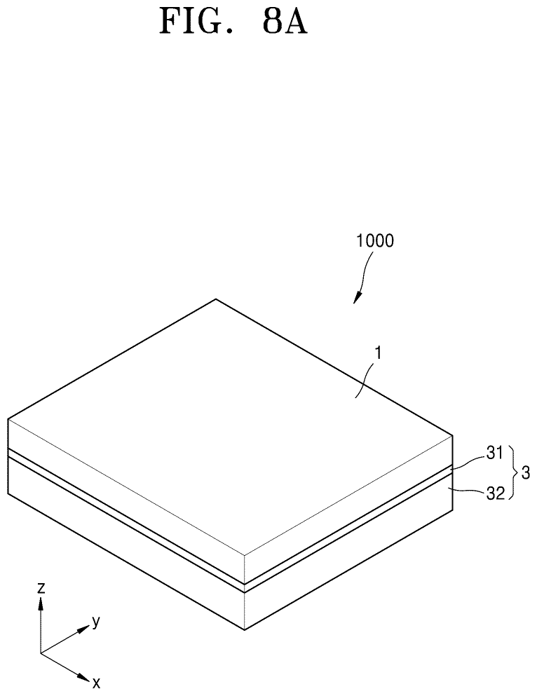

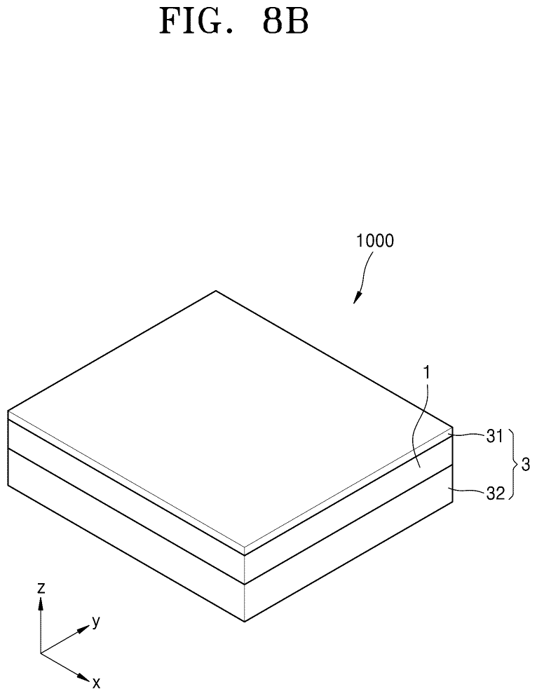

FIGS. 8A and 8B are perspective views schematically illustrating an electronic device 1000 according to an embodiment of the present disclosure.

Referring to FIGS. 8A and 8B, the electronic device 1000 may include the display apparatus 1 and a pressing unit 3.

The pressing unit 3 may be fixed to the display apparatus 1 and press the display apparatus 1 in a thickness direction, that is, the third direction (for example, the z direction and/or the −z direction). Expressed another way, the pressing unit 3 may apply a force to (i.e., apply a force against) the display apparatus 1 in the thickness direction, that is, the third direction (for example, a pushing force in the z direction and/or a puling force in the −z direction).

The pressing unit 3 may include a plate portion 31 and a pressing module 32. The pressing unit 3, the plate portion 31, and the pressing module 32 may be stacked in the thickness direction, that is, the third direction (for example, the z direction and/or the −z direction). For example, the planar shapes of the display apparatus 1, the plate portion 31, and the pressing module 32 may correspond to each other. The plate portion 31 is stretchable and may be fixed to the display apparatus 1.

The pressing module 32 may press the plate portion 31 in the thickness direction, that is, the third direction (for example, the z direction and/or the −z direction). Expressed another way, the pressing module 32 may apply a force to (i.e., apply a force against) the plate portion 31 in the thickness direction, that is, the third direction (for example, a pushing force in the z direction and/or a pulling force in the −z direction).

For example, as illustrated in FIG. 8A, the plate portion 31 may be arranged on the pressing module 32, and the display apparatus 1 may be arranged on the plate portion 31. In this structure, when the pressing module 32 applies a force to the plate portion 31, the force may also be applied to the display apparatus 1 fixed to the plate portion 31.

For example, as illustrated in FIG. 8B, the display apparatus 1 may be arranged on the pressing module 32, and the plate portion 31 may be arranged on the display apparatus 1. In this case, the plate portion 31 may include a transparent material. In this structure, when the pressing module 32 applies a force to the plate portion 31, the force may also be applied to the display apparatus 1 arranged between the pressing module 32 and the plate portion 31.

However, this is an example, and the arrangement of the pressing module 32, the plate portion 31, and the display apparatus 1 is not limited thereto. For example, the plate portion 31 may be arranged within the display apparatus 1, and the plate portion 31 may be a component of the display apparatus 1.

Hereinafter, as illustrated in FIG. 8A, the following will be described assuming that the plate portion 31 is arranged on the pressing module 32 and the display apparatus 1 is arranged on the plate portion 31.

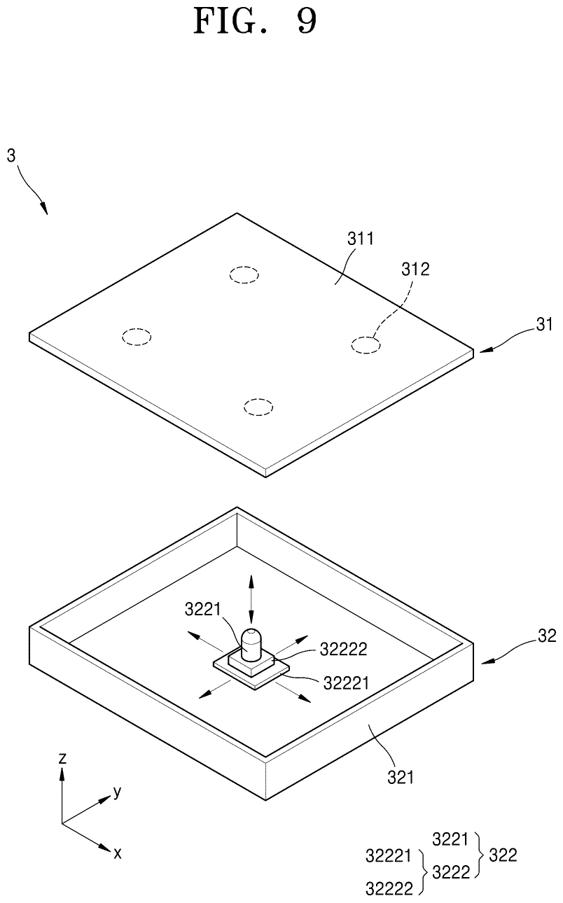

FIG. 9 is an exploded perspective view schematically illustrating the pressing unit 3 according to an embodiment of the present disclosure.

Referring to FIG. 9, the pressing unit 3 may include the plate portion 31 and the pressing module 32.

The plate portion 31 may be arranged on a frame portion 321 described herein. The plate portion 31 may have magnetism. For example, the plate portion 31 may include a metal material. The plate portion 31 may include a first area 311 and a plurality of second areas 312 having elongations different from an elongation of from the first area 311. For example, the plurality of second areas 312 may each have an elongation smaller than an elongation of the first area 311. For example, at least two of the plurality of second areas 312 may have elongations different from each other.

Due to the arrangement of the plurality of second areas 312, when a stroke module 322 applies a force to the plate portion 31 and the display apparatus 1 (see FIG. 8A), the plate portion 31 may be elongated into a desired or target shape. In some aspects, due to the arrangement of the plurality of second areas 312, when the stroke module 322 applies a force to the plate portion 31, a phenomenon in which strain and stress are concentrated in certain areas of the plate portion 31 and the display apparatus 1 (see FIG. 8A) may be reduced. The elongations of the plurality of second areas 312 may be designed in various ways in consideration of target or desired factors. For example, the elongations of the plurality of second areas 312 may be adjusted by forming grooves and/or holes in the plate portion 31.

The term “elongation” used herein may refer to a dimension of an element (e.g., plate portion 31, area 311, area 312, and other elements described herein) with respect to a particular direction (e.g., x direction, −x direction, y direction, −y direction, z direction, −z direction).

The plurality of second areas 312 may be spaced apart from each other. Each of the plurality of second areas 312 may be provided in the form of an island. FIG. 9 illustrates that the plurality of second areas 312 are arranged symmetrically in the form of four circular shapes, but this is an example, and the number, shape, and arrangement of the plurality of second areas 312 are not limited thereto.

The pressing module 32 may include the frame portion 321 and the stroke module 322. The frame portion 321 may form an exterior of the pressing module 32 and perform a housing function. The stroke module 322 may be arranged in an internal space of the frame portion 321, and the frame portion 321 may protect the stroke module 322 from the outside.

The stroke module 322 may be arranged between the frame portion 321 and the plate portion 31. The stroke module 322 may be supported by the frame portion 321. The stroke module 322 may move in the first direction (for example, the x direction and/or the −x direction) and the second direction (for example, the y direction and/or the −y direction) with respect to the frame portion 321. The stroke module 322 may apply the force to the plate portion 31 in the third direction (for example, the z direction and/or the −z direction). The stroke module 322 may include a stroke unit 3221 and a moving unit 3222.

The stroke unit 3221 may extend in the third direction (for example, the z direction and/or the −z direction) and may be provided with a rounded end facing the plate portion 31. The stroke unit 3221 may be switched between a first state with magnetism and a second state with no magnetism. For example, the stroke unit 3221 may include at least one of an electromagnet and an electropermanent magnet.

The moving unit 3222 may move the stroke unit 3221 with respect to the frame portion 321. The moving unit 3222 may be supported by the frame portion 321. The moving unit 3222 may support the stroke unit 3221. The moving unit 3222 may move the stroke unit 3221 in the first direction (for example, the x direction and/or the −x direction), the second direction (for example, the y direction and/or the −y direction), and the third direction (for example, the z direction and/or the −z direction) with respect to the frame portion 321. In detail, the moving unit 3222 may move the stroke unit 3221 in a third-1 direction (for example, the z direction) toward the plate portion 31 and a third-2 direction (for example, the −z direction) away from the plate portion 31 with respect to the frame portion 321.

The moving unit 3222 may include a first moving portion 32221 and a second moving portion 32222. The first moving portion 32221 may move the stroke unit 3221 in the first direction (for example, the x direction and/or the −x direction) and the second direction (for example, the y direction and/or the −y direction). The second moving portion 32222 may move the stroke unit 3221 in the third direction (for example, the z direction and/or the −z direction). For example, as illustrated in FIG. 9, the first moving portion 32221 may be arranged on the frame portion 321, the second moving portion 32222 may be arranged on the first moving portion 32221, and the stroke unit 3221 may be arranged on the second moving portion 32222. However, this is an example, and the arrangement of the first moving portion 32221 and the second moving portion 32222 is not limited thereto. For example, each of the first moving portion 32221 and the second moving portion 32222 may include a linear motor. However, this is an example, and the configuration for driving the first moving portion 32221 and the second moving portion 32222 is not limited thereto.

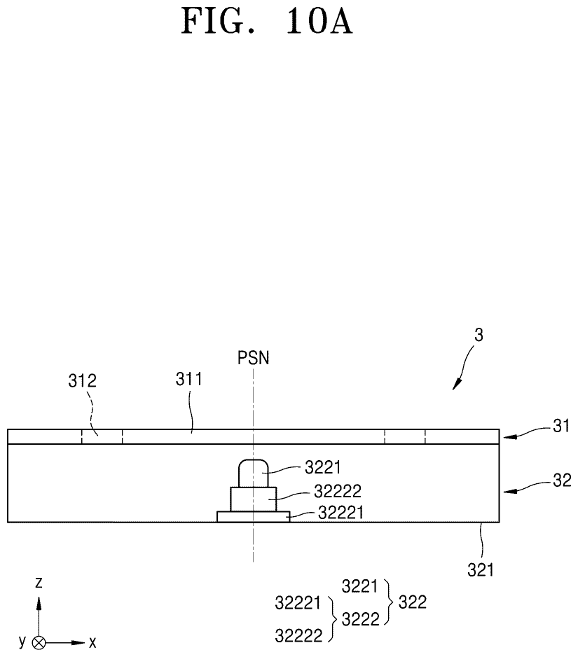

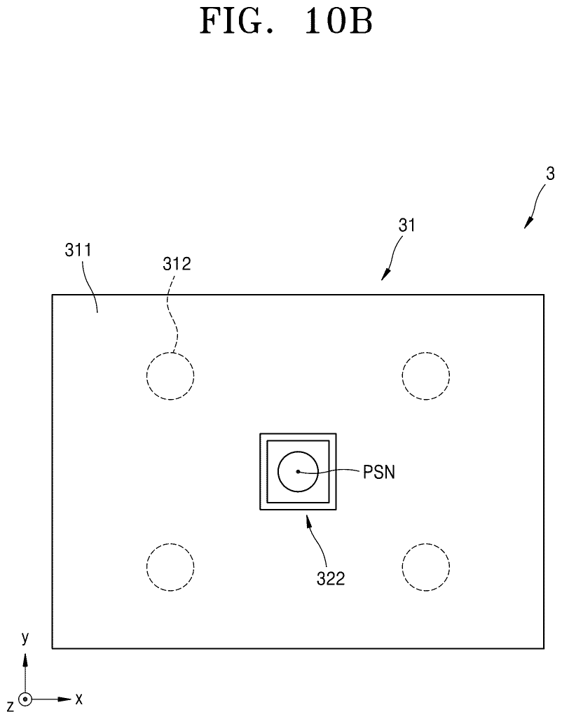

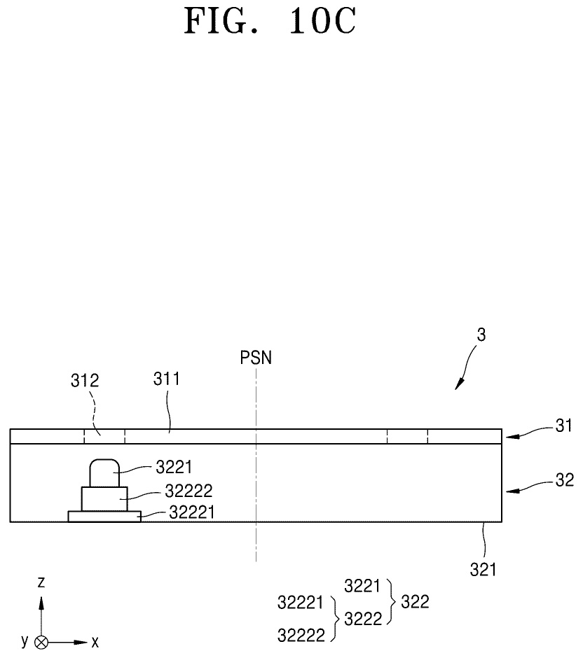

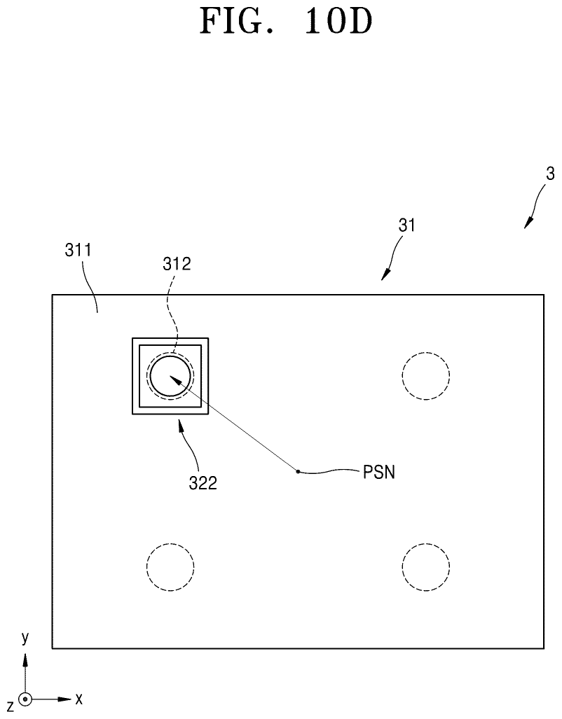

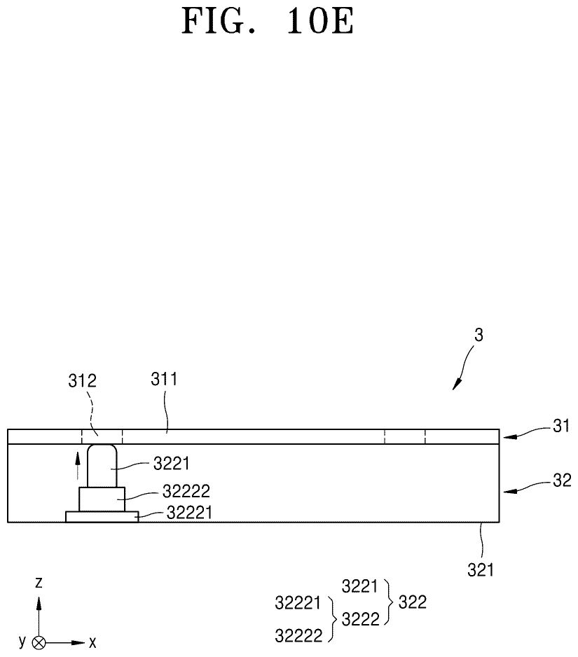

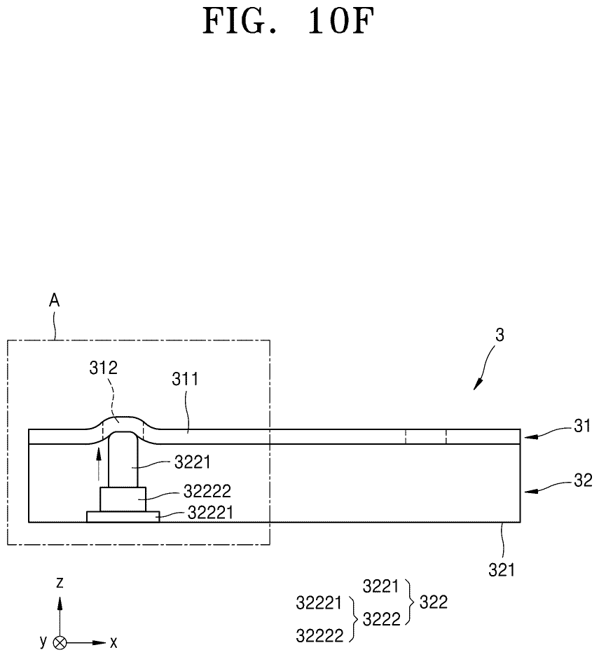

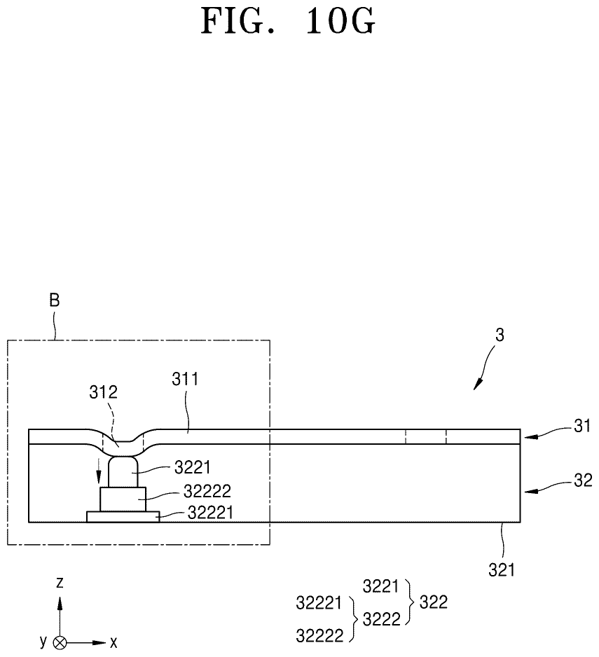

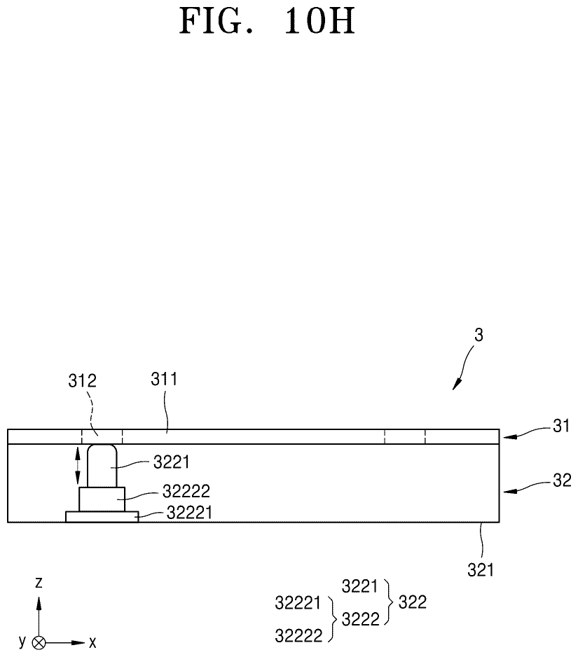

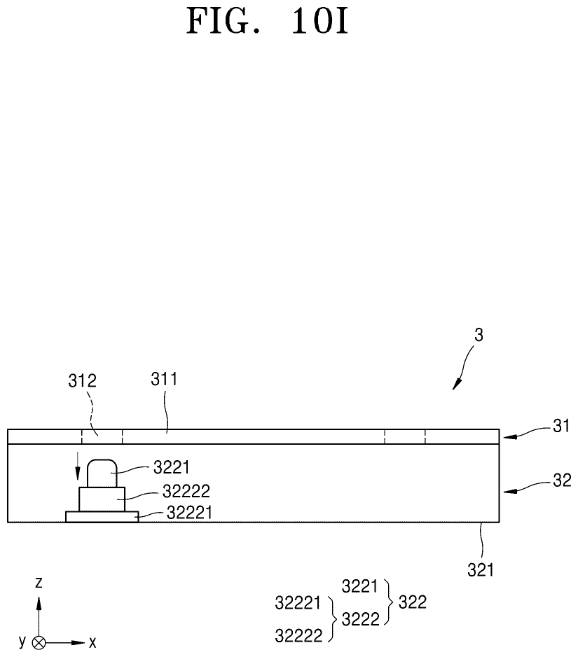

FIG. 10A is a cross-sectional view schematically illustrating the pressing unit 3 according to an embodiment of the present disclosure, FIG. 10B is a plan view schematically illustrating the pressing unit 3 according to an embodiment of the present disclosure, FIG. 10C is a cross-sectional view schematically illustrating the pressing unit 3 according to an embodiment of the present disclosure, FIG. 10D is a plan view schematically illustrating the pressing unit 3 according to an embodiment of the present disclosure, and FIGS. 10E to 10I are cross-sectional views schematically illustrating the pressing unit 3 according to an embodiment of the present disclosure.

In detail, FIG. 10B is a schematic plan view of the pressing unit 3 corresponding to FIG. 10A, and FIG. 10D is a schematic plan view of the pressing unit 3 corresponding to FIG. 10C.

Regarding FIGS. 10A to 10I, reference numerals identical to those in FIG. 9 refer to the same components, and redundant descriptions thereof are omitted.

Referring to FIGS. 10A to 10I, a process in which the pressing module 32 applies a force to the plate portion 31 may be understood.

First, referring to FIGS. 10A and 10B, the stroke module 322 may be arranged at a neutral position PSN within the frame portion 321. In this case, the stroke unit 3221 may be in the second state. The moving unit 3222, specifically, the first moving portion 32221, may move the stroke unit 3221 in the first direction (for example, the x direction and/or the −x direction) and the second direction (for example, the y direction and/or the −y direction), such that the stroke unit 3221 is arranged at the neutral position PSN. For example, the neutral position PSN may be a position passing through a center of the plate portion 31 in a plan view. For example, the neutral position PSN may be arranged equidistant from the plurality of second areas 312 in a plan view.

Referring to FIGS. 10C and 10D, the stroke module 322 may move to a position that overlaps any one of the plurality of second areas 312. The stroke unit 3221 may maintain the second state. The moving unit 3222, specifically, the first moving portion 32221, may move the stroke unit 3221 in the first direction (for example, the x direction and/or the −x direction) and the second direction (for example, the y direction and/or the −y direction), such that the stroke unit 3221 overlaps any one of the plurality of second areas 312.

Referring to FIG. 10E, the stroke module 322 may be in contact with the plate portion 31. The moving unit 3222, specifically, the second moving portion 32222, may move the stroke unit 3221 in the third-1 direction (for example, the z direction) with respect to the frame portion 321, such that the stroke unit 3221 is in contact with one of the plurality of second areas 312. In this case, the stroke unit 3221 may be switched from the second state to the first state. A magnetic force may act between the stroke unit 3221, which has magnetism, and the plate portion 31. In detail, an attractive force may act between the stroke unit 3221 and the plate portion 31.

Referring to FIGS. 10F and 10G, the stroke module 322 may apply the force to the plate portion 31 in the first state, at a position where the stroke unit 3221 overlaps any one of the plurality of second areas 312. In other words, in a state where an attractive force acts between the stroke unit 3221 and the plate portion 31, the stroke unit 3221 may press against (i.e., apply a pushing force) the plate portion 31.

For example, as illustrated in FIG. 10F, the stroke unit 3221 may press against (i.e., apply the pushing force) the plate portion 31 in the third-1 direction (for example, the z direction). The moving unit 3222, specifically, the second moving portion 32222, may move the stroke unit 3221 in the third-1 direction (for example, the z direction), in a state where the stroke unit 3221 is in contact with the plate portion 31. As the stroke unit 3221 applies the force to the plate portion 31 in the third-1 direction (for example, the z direction), thus pressing against the plate portion 31 in the third-1 direction (for example, the z direction), a partial area (for example, any one of the plurality of second areas 312) of the plate portion 31 may be elongated in the third-1 direction (for example, the z direction). In this process, at least a portion of the display apparatus 1 (see FIG. 8A) fixed to the plate portion 31 may be elongated in the third-1 direction (for example, the z direction). Therefore, a convex area may be formed on the plate portion 31 and the display apparatus 1 (see FIG. 8A).

For example, as illustrated in FIG. 10G, the stroke unit 3221 may apply a force (i.e., a pulling force) to the plate portion 31 in the third-2 direction (for example, the −z direction). The moving unit 3222, specifically, the second moving portion 32222, may move the stroke unit 3221 in the third-2 direction (for example, the −z direction), in a state where the stroke unit 3221 is in contact with the plate portion 31. As the stroke unit 3221 applies the force to the plate portion 31 in the third-2 direction (for example, the −z direction), thus pulling the plate portion 31 in the third-2 direction (for example, the −z direction), a partial area (for example, any one of the plurality of second areas 312) of the plate portion 31 may be elongated in the third-2 direction (for example, the −z direction). In this process, at least a portion of the display apparatus 1 (see FIG. 8A) fixed to the plate portion 31 may be elongated in the third-2 direction (for example, the −z direction). Therefore, a concave area may be formed on the plate portion 31 and the display apparatus 1 (see FIG. 8A).

The shape of the plate portion 31 after elongation may be adjusted in various ways according to the elongations of the first area 311 and the plurality of second areas 312 and the strength of magnetism between the plate portion 31 and the stroke unit 3221.

Referring to FIG. 10H, the stroke unit 3221 may move in the third-1 direction (for example, the z direction) and/or the third-2 direction (for example, the −z direction), such that the plate portion 31 becomes flat. The moving unit 3222, specifically, the second moving portion 32222, may move the stroke unit 3221 in the third-1 direction (for example, the z direction) and/or the third-2 direction (for example, the −z direction) with respect to the frame portion 321, such that the plate portion 31 is not elongated. In this case, the stroke unit 3221 may be switched from the first state to the second state. Because the magnetism of the stroke unit 3221 is dissipated, a magnetic force may not act between the stroke unit 3221 and the plate portion 31. In detail, an attractive force may not act between the stroke unit 3221 and the plate portion 31.

Referring to FIG. 10I, the stroke unit 3221 may move in the third-2 direction (for example, the −z direction) such that the stroke unit 3221 is spaced apart from the plate portion 31. The moving unit 3222, specifically, the second moving portion 32222, may move the stroke unit 3221 in the third-2 direction (for example, the −z direction) with respect to the frame portion 321, such that the stroke unit 3221 is spaced apart from the plate portion 31. The stroke unit 3221 may maintain the second state.

Afterwards, as described with reference to FIGS. 10A and 10B, the stroke module 322 may move to the neutral position PSN within the frame portion 321. The stroke unit 3221 may maintain the second state.

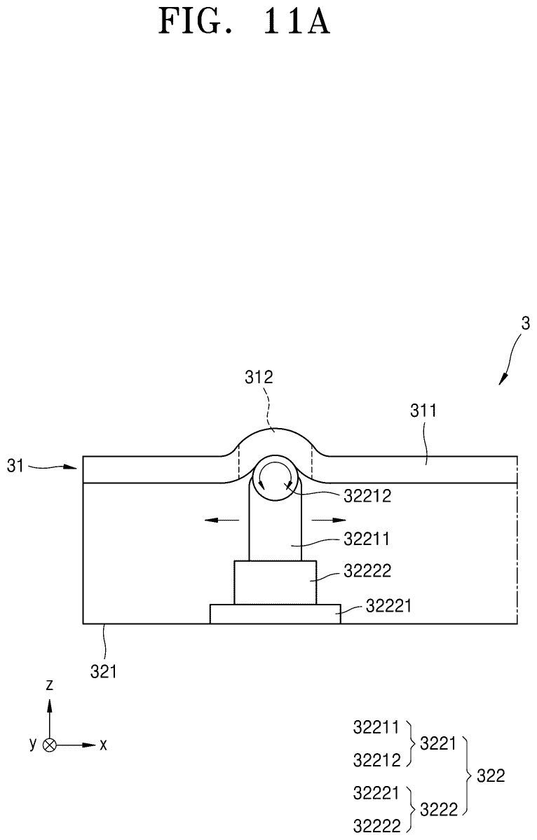

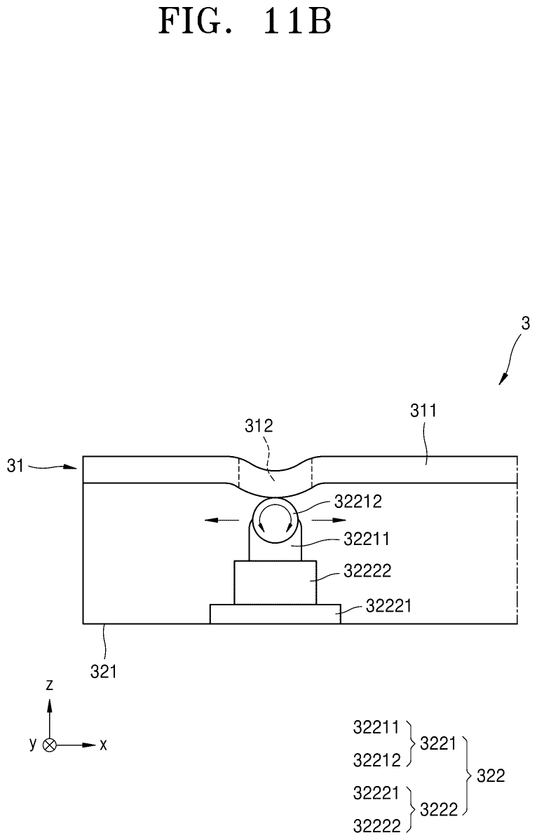

FIG. 11A is a cross-sectional view schematically illustrating the pressing unit 3 according to an embodiment of the present disclosure, and FIG. 11B is a cross-sectional view schematically illustrating the pressing unit 3 according to an embodiment of the present disclosure.

In detail, FIG. 11A is an enlarged view of an area A of FIG. 10F, and FIG. 11B is an enlarged view of an area B of FIG. 10G.

Regarding FIGS. 11A and 11B, reference numerals identical to those in FIGS. 9 to 10G refer to the same components, and redundant descriptions thereof are omitted.

Referring to FIGS. 11A and 11B, a process in which the pressing module 32 applies a force to the plate portion 31 may be understood.

The stroke unit 3221 may include a body portion 32211 and a roller portion 32212.

The body portion 32211 may extend in the third direction (for example, the z direction and/or the −z direction) and may be connected to the moving unit 3222. The second moving portion 32222 may move the body portion 32211 in the third-1 direction (for example, the z direction) and/or the third-2 direction (for example, the −z direction). The roller portion 32212 may be connected to the body portion 32211 in the third-1 direction (for example, the z direction) and be freely rotatable with respect to the body portion 32211. The roller portion 32212 may freely rotate about the first direction (for example, the x direction and/or the −x direction), the second direction (for example, the y direction and/or the −y direction), and/or the third direction (for example, the z direction and/or the −z direction) with respect to the body portion 32211. For example, the roller portion 32212 and the body portion 32211 may be coupled to each other in the form of a ball caster.

In a state where the pressing unit 3 applies a force to the display apparatus 1 (see FIG. 8A), the stroke module 322 may move in at least one direction among the first direction (for example, the x direction and/or the −x direction) and the second direction (for example, the y direction and/or the −y direction) with respect to the frame portion 321. For example, as illustrated in FIG. 11A, in a state where the stroke module 322 applies a force to the plate portion 31 in the third-1 direction (for example, the z direction), the stroke unit 3221 may move in the first direction (for example, the x direction and/or the −x direction) and/or the second direction (for example, the y direction and/or the −y direction). For example, as illustrated in FIG. 11B, in a state where the stroke module 322 applies a force to the plate portion 31 in the third-2 direction (for example, the −z direction), the stroke unit 3221 may move in the first direction (for example, the x direction and/or the −x direction) and/or the second direction (for example, the y direction and/or the −y direction).

In this case, the roller portion 32212 of the stroke unit 3221 may be in contact with the plate portion 31. In a process where the stroke module 322 moves, the roller portion 32212 may rotate with respect to the body portion 32211. Therefore, a phenomenon in which the plate portion 31 is pushed or rubbed in the first direction (for example, the x direction and/or the −x direction) and/or the second direction (for example, the y direction and/or the −y direction) may be reduced due to a frictional force between the stroke unit 3221 and the plate portion 31.

The duration for which the stroke module 322 applies a force to the plate portion 31, the height of the stroke unit 3221, and the strength of magnetic force between the stroke unit 3221 and the plate portion 31 may be designed in various ways in consideration of target or desired factors. In some aspects, the stroke module 322 may not only perform a function of elongating the display apparatus 1 (see FIG. 8A) but also a function of a button that recognizes external stimuli (finger pressing, pen touch, or the like).

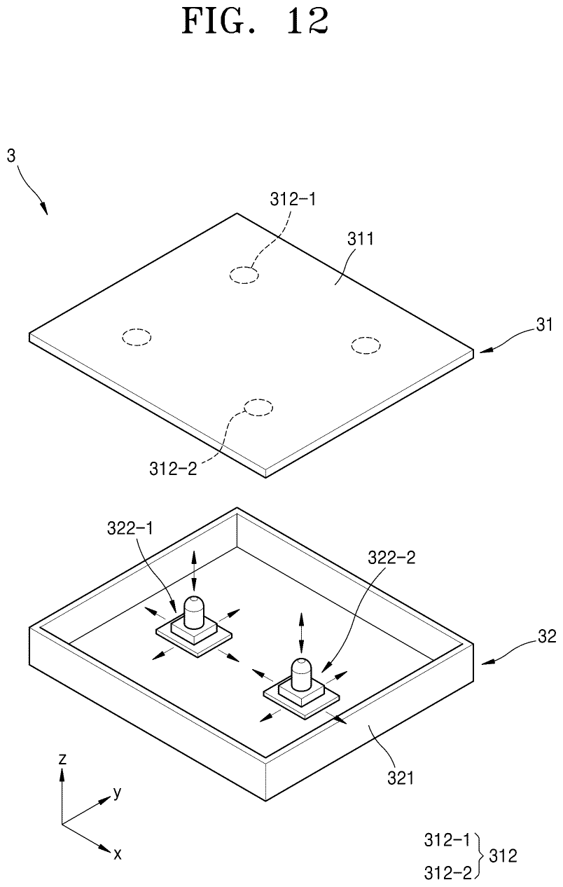

FIG. 12 is an exploded perspective view schematically illustrating the pressing unit 3 according to an embodiment of the present disclosure.

Regarding FIG. 12, reference numerals identical to those in FIG. 9 refer to the same components, and redundant descriptions thereof are omitted.

Referring to FIG. 12, the pressing unit 3 may include the plate portion 31 and the pressing module 32.

The plate portion 31 may have magnetism. For example, the plate portion 31 may include a metal material. The plate portion 31 may include the first area 311 and the plurality of second areas 312 having elongations different from an elongation of from the first area 311. Hereinafter, any one of the plurality of second areas 312 is referred to as a second-1 area 312-1, and another one of the plurality of second areas 312 is referred to as a second-2 area 312-2.

The pressing module 32 may include the frame portion 321 and the stroke module 322. The frame portion 321 may form an exterior of the pressing module 32 and perform a housing function.

The stroke module 322 may be arranged between the frame portion 321 and the plate portion 31. The stroke module 322 may be supported by the frame portion 321. The stroke module 322 may apply a force to the plate portion 31 in the third direction (for example, a pushing force in the z direction and/or a pulling force in the −z direction). The stroke module 322 may be provided as a plurality of stroke modules 322. The plurality of stroke modules 322 may move independently from one another. Each of the plurality of stroke modules 322 may move in the first direction (for example, the x direction and/or the −x direction) and/or the second direction (for example, the y direction and/or the −y direction) with respect to the frame portion 321. The plurality of stroke modules 322 may apply a force to the plate portion 31 at different positions, respectively.

For example, as illustrated in FIG. 12, the plurality of stroke modules 322 may include a first stroke module 322-1 and a second stroke module 322-2. The first stroke module 322-1 and the second stroke module 322-2 may be spaced apart from each other in the first direction (for example, the x direction and/or the −x direction). The first stroke module 322-1 and the second stroke module 322-2 may each include the moving unit 3222 and may move independently from one another.

The number of the plurality of second areas 312 may be greater than the number of the plurality of stroke modules 322. For example, as illustrated in FIG. 12, the plurality of stroke modules 322 may be provided as two, and the plurality of second areas 312 may be provided as four. However, this is an example, and the number of the plurality of stroke modules 322 and the number of the plurality of second areas 312 are not limited thereto. For example, the plurality of stroke modules 322 may be provided as five, and the plurality of second areas 312 may be provided as 25. Hereinafter, the following will be described assuming that the plurality of stroke modules 322 include the first stroke module 322-1 and the second stroke module 322-2.

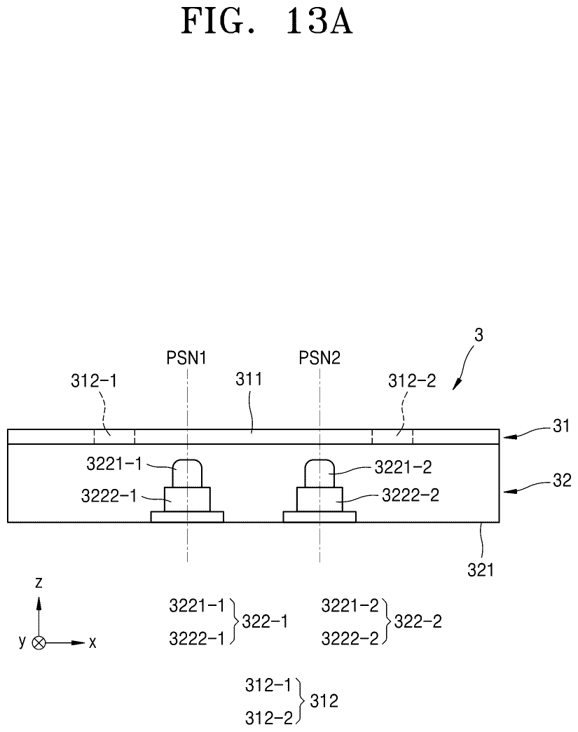

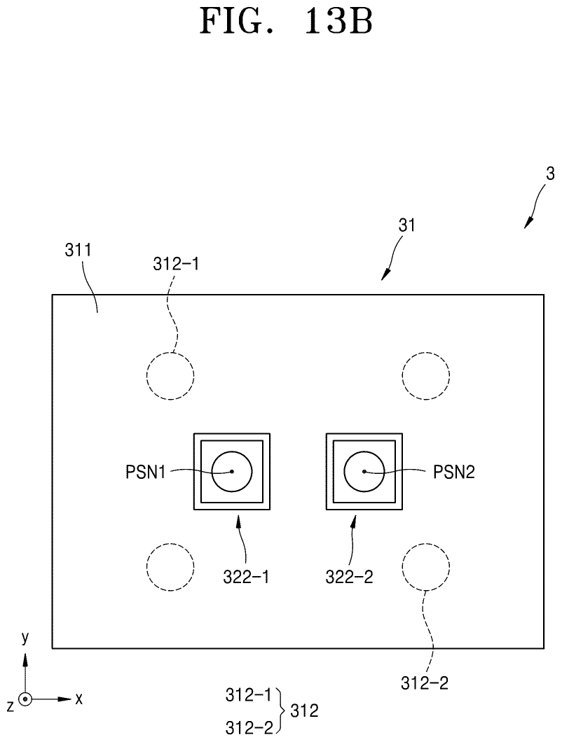

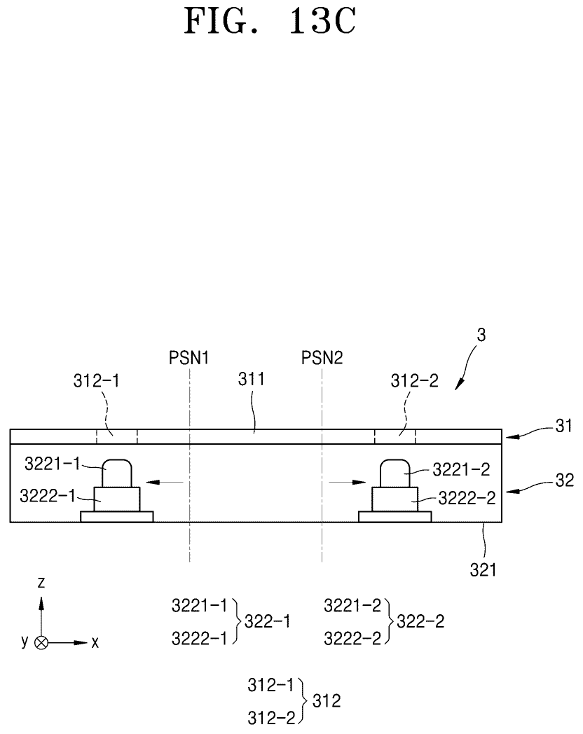

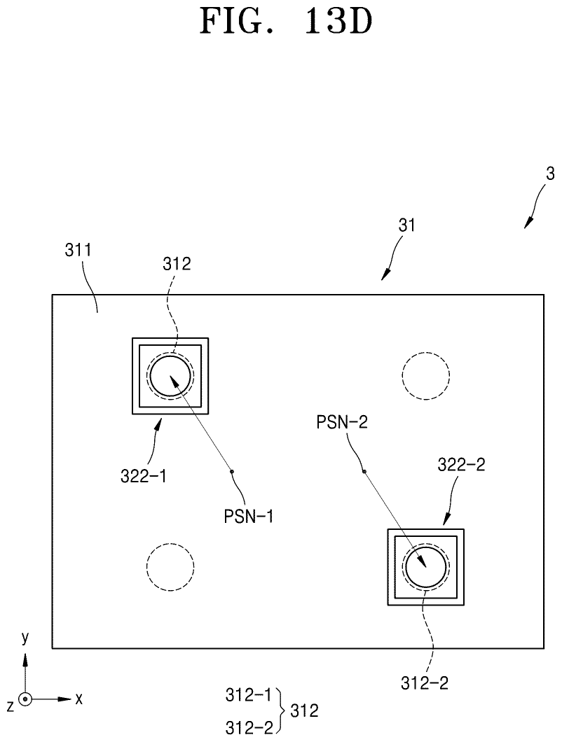

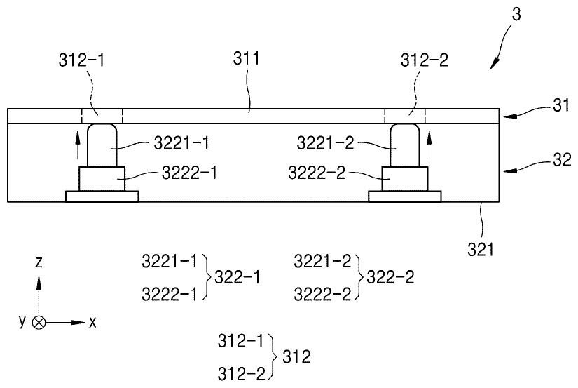

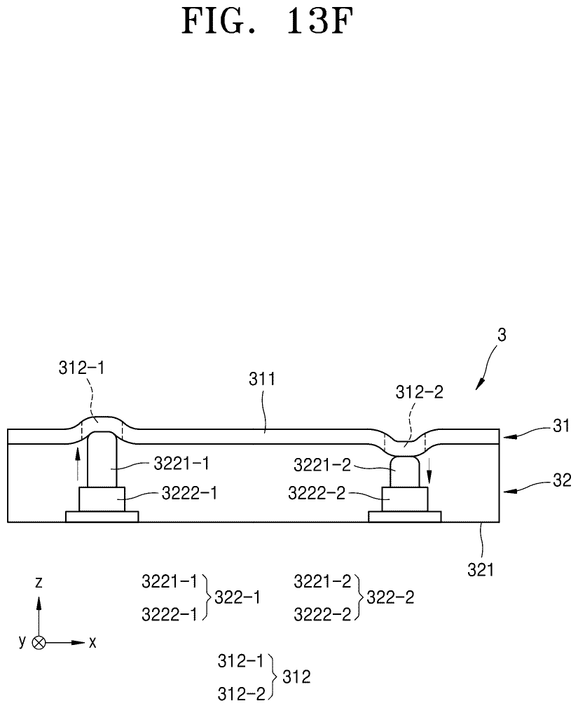

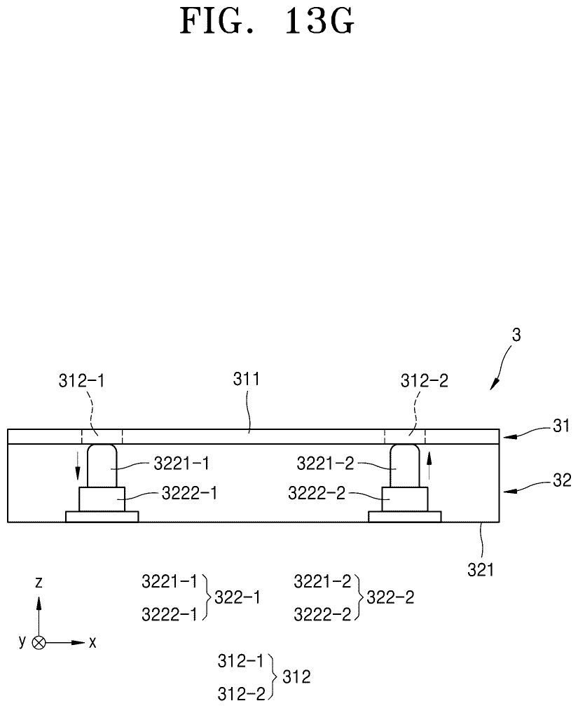

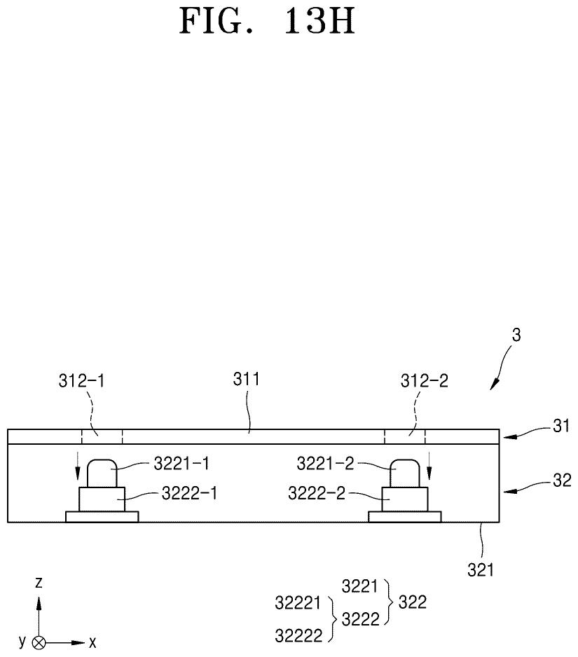

FIG. 13A is a cross-sectional view schematically illustrating the pressing unit 3 according to an embodiment of the present disclosure, FIG. 13B is a plan view schematically illustrating the pressing unit 3 according to an embodiment of the present disclosure, FIG. 13C is a cross-sectional view schematically illustrating the pressing unit 3 according to an embodiment of the present disclosure, FIG. 13D is a plan view schematically illustrating the pressing unit 3 according to an embodiment of the present disclosure, and FIGS. 13E to 13H are cross-sectional views schematically illustrating the pressing unit 3 according to an embodiment of the present disclosure.

In detail, FIG. 13B is a schematic plan view of the pressing unit 3 corresponding to FIG. 13A, and FIG. 13D is a schematic plan view of the pressing unit 3 corresponding to FIG. 13C.

Regarding FIGS. 13A to 13I, reference numerals identical to those in FIG. 12 refer to the same components, and redundant descriptions thereof are omitted.

Referring to FIGS. 13A to 13I, the first stroke module 322-1 may include a first stroke unit 3221-1 and a first moving unit 3222-1, and the second stroke module 322-2 may include a second stroke unit 3221-2 and a second moving unit 3222-2.

Each of the first stroke unit 3221-1 and the second stroke unit 3221-2 may have the same structure as the stroke unit 3221 described with reference to FIG. 9. Each of the first stroke unit 3221-1 and the second stroke unit 3221-2 may extend in the third direction (for example, the z direction and/or the −z direction) and may have a rounded end facing the plate portion 31. Each of the first stroke unit 3221-1 and the second stroke unit 3221-2 may be switched between a first state having magnetism (also referred to herein as a magnetic state) and a second state with no magnetism (also referred to herein as a non-magnetic state).

Each of the first moving unit 3222-1 and the second moving unit 3222-2 may have the same structure as the stroke unit 3221 described with reference to FIG. 9. The first moving unit 3222-1 may move the first stroke unit 3221-1 in the first direction (for example, the x direction and/or the −x direction), the second direction (for example, the y direction and/or the −y direction), and the third direction (for example, the z direction and/or the −z direction) with respect to the frame portion 321. In detail, the first moving unit 3222-1 may move the first stroke unit 3221-1 in the third-1 direction (for example, the z direction) and the third-2 direction (for example, the −z direction) with respect to the frame portion 321. The second moving unit 3222-2 may move the second stroke unit 3221-2 in the first direction (for example, the x direction and/or the −x direction), the second direction (for example, the y direction and/or the −y direction), and the third direction (for example, the z direction and/or the −z direction) with respect to the frame portion 321. In detail, the second moving unit 3222-2 may move the second stroke unit 3221-2 in the third-1 direction (for example, the z direction) and the third-2 direction (for example, the −z direction) with respect to the frame portion 321.

First, referring to FIGS. 13A and 13B, the first stroke module 322-1 may be arranged at a first neutral position PSN1 within the frame portion 321, and the second stroke module 322-2 may be arranged at a second neutral position PSN2 within the frame portion 321. In this case, each of the first stroke unit 3221-1 and the second stroke unit 3221-2 may be in the second state.

The first moving unit 3222-1 may move the first stroke unit 3221-1 in the first direction (for example, the x direction and/or the −x direction) and the second direction (for example, the y direction and/or the −y direction), such that the first stroke unit 3221-1 is arranged at the first neutral position PSN1. The second moving unit 3222-2 may move the second stroke unit 3221-2 in the first direction (for example, the x direction and/or the −x direction) and the second direction (for example, the y direction and/or the −y direction), such that the second stroke unit 3221-2 is arranged at the second neutral position PSN2.

For example, the first neutral position PSN1 and the second neutral position PSN2 may be symmetrical to each other with respect to a center of the plate portion 31 in a plan view. For example, the first neutral position PSN1 and the second neutral position PSN2 may be spaced apart from each other in the first direction (for example, the x direction and/or the −x direction). The first neutral position PSN1 and the second neutral position PSN2 may be set at various positions in consideration of efficient movement paths of the first stroke module 322-1 and the second stroke module 322-2, which are described herein.

Referring to FIGS. 13C and 13D, the first stroke module 322-1 may move to a position that overlaps any one of the plurality of second areas 312, and the second stroke module 322-2 may move to a position that overlaps another one of the plurality of second areas 312. For example, the first stroke module 322-1 may move to overlap the second-1 area 312-1, and the second stroke module 322-2 may move to overlap the second-2 area 312-2. The stroke unit 3221 may maintain the second state. The first moving unit 3222-1 may move the first stroke unit 3221-1 in the first direction (for example, the x direction and/or the −x direction) and the second direction (for example, the y direction and/or the −y direction), such that the first stroke unit 3221-1 overlaps the second-1 area 312-1. The second moving unit 3222-2 may move the second stroke unit 3221-2 in the first direction (for example, the x direction and/or the −x direction) and the second direction (for example, the y direction and/or the −x direction), such that the second stroke unit 3221-2 overlaps the second-2 area 312-2.

Referring to FIG. 13E, each of the first stroke module 322-1 and the second stroke module 322-2 may be in contact with the plate portion 31.

The first moving unit 3222-1 may move the first stroke unit 3221-1 in the third-1 direction (for example, the z direction) with respect to the frame portion 321, such that the first stroke unit 3221-1 is in contact with the second-1 area 312-1. The second moving unit 3222-2 may move the second stroke unit 3221-2 in the third-1 direction (for example, the z direction) with respect to the frame portion 321, such that the second stroke unit 3221-2 is in contact with the second-2 area 312-2. In this case, each of the first stroke unit 3221-1 and the second stroke unit 3221-2 may be switched from the second state to the first state. A magnetic force (specifically, an attractive force) may act between the first stroke unit 3221-1, which has magnetism, and the plate portion 31. A magnetic force (specifically, an attractive force) may act between the second stroke unit 3221-2, which has magnetism, and the plate portion 31.

However, embodiments of the present disclosure are not limited thereto. For example, in some aspects, the first moving unit 3222-1 may move the first stroke unit 3221-1 in the third-1 direction (for example, the z direction) with respect to the frame portion 321, such that the first stroke unit 3221-1 is in contact with the second-1 area 312-1, while the first stroke unit 3221-1 is in the second state (i.e., non-magnetic state).

Referring to FIG. 13F, the first stroke unit 3221-1 may apply a force (i.e., a pushing force) to the plate portion 31 in the first state, at a position where the first stroke module 322-1 overlaps the second-1 area 312-1. The second stroke unit 3221-2 may apply a force (i.e., a pulling force) to the plate portion 31 in the first state, at a position where the second stroke module 322-2 overlaps the second-2 area 312-2.

For example, as illustrated in FIG. 13F, the first stroke unit 3221-1 may apply the force (i.e., pushing force) to the plate portion 31 in the third-1 direction (for example, the z direction). The first moving unit 3222-1 may move the first stroke unit 3221-1 in the third-1 direction (for example, the z direction), in a state where the first stroke unit 3221-1 is in contact with the plate portion 31. As the first stroke unit 3221-1 applies the force to the plate portion 31 in the third-1 direction (for example, the z direction), thus pressing against the plate portion 31 in the third-1 direction (for example, the z direction), a partial area (for example, the second-1 area 312-1) of the plate portion 31 may be elongated in the third-1 direction (for example, the z direction). In this process, at least a portion of the display apparatus 1 (see FIG. 8A) fixed to the plate portion 31 may be elongated in the third-1 direction (for example, the z direction).

For example, as illustrated in FIG. 13F, the second stroke unit 3221-2 may apply the force (i.e., pulling force) to the plate portion 31 in the third-2 direction (for example, the −z direction). The second moving unit 3222-2 may move the second stroke unit 3221-2 in the third-2 direction (for example, the −z direction), in a state where the second stroke unit 3221-2 is in contact with the plate portion 31. As the second stroke unit 3221-2 applies the force to the plate portion 31 in the third-2 direction (for example, the −z direction), thus pulling the plate portion 31 in the third-2 direction (for example, the −z direction), a partial area (for example, the second-2 area 312-2) of the plate portion 31 may be elongated in the third-2 direction (for example, the −z direction). In this process, at least a portion of the display apparatus 1 (see FIG. 8A) fixed to the plate portion 31 may be elongated in the third-2 direction (for example, the −z direction).

Referring to FIG. 13G, each of the first stroke unit 3221-1 and the second stroke unit 3221-2 may move in the third-1 direction (for example, the z direction) or the third-2 direction (for example, the −z direction), such that the plate portion 31 becomes flat. For example, the first moving unit 3222-1 may move the first stroke unit 3221-1 in the third-2 direction (for example, the −z direction) with respect to the frame portion 321, such that the plate portion 31 is not elongated. For example, the second moving unit 3222-2 may move the second stroke unit 3221-2 in the third-1 direction (for example, the z direction) with respect to the frame portion 321, such that the plate portion 31 is not elongated. In this case, each of the first stroke unit 3221-1 and the second stroke unit 3221-2 may be switched from the first state to the second state. Because the magnetism of the first stroke unit 3221-1 is dissipated, a magnetic force (specifically, an attractive force) may not act between the first stroke unit 3221-1 and the plate portion 31. Because the magnetism of the second stroke unit 3221-2 is dissipated, a magnetic force (specifically, an attractive force) may not act between the second stroke unit 3221-2 and the plate portion 31.

Referring to FIG. 13H, each of the first stroke unit 3221-1 and the second stroke unit 3221-2 may move in the third-2 direction (for example, the −z direction) such that the first stroke unit 3221-1 and the second stroke unit 3221-2 are spaced apart from the plate portion 31. The first moving unit 3222-1 may move the first stroke unit 3221-1 in the third-2 direction (for example, the −z direction) with respect to the frame portion 321, such that the first stroke unit 3221-1 is spaced apart from the plate portion 31. The second moving unit 3222-2 may move the second stroke unit 3221-2 in the third-2 direction (for example, the −z direction) with respect to the frame portion 321, such that the second stroke unit 3221-2 is spaced apart from the plate portion 31. In this case, the first stroke unit 3221-1 and the second stroke unit 3221-2 may maintain the second state.

Hereinafter, as described with reference to FIGS. 13A and 13B, the first stroke module 322-1 may move to the first neutral position PSN1 within the frame portion 321. In some aspects, the second stroke module 322-2 may move to the second neutral position PSN2 within the frame portion 321. In this case, the first stroke unit 3221-1 and the second stroke unit 3221-2 may maintain the second state.

The display apparatus 1 according to the above-described embodiments may be used in various electronic devices that are capable of providing images. Herein, the electronic devices refer to devices that use electricity and are capable of providing certain images.

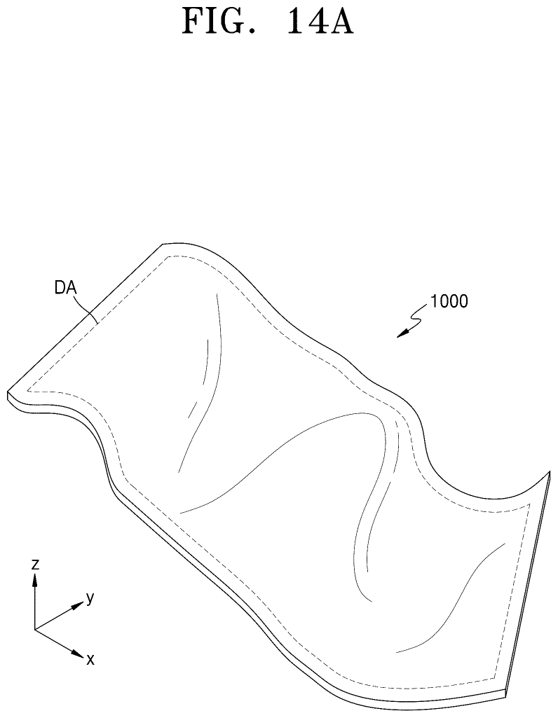

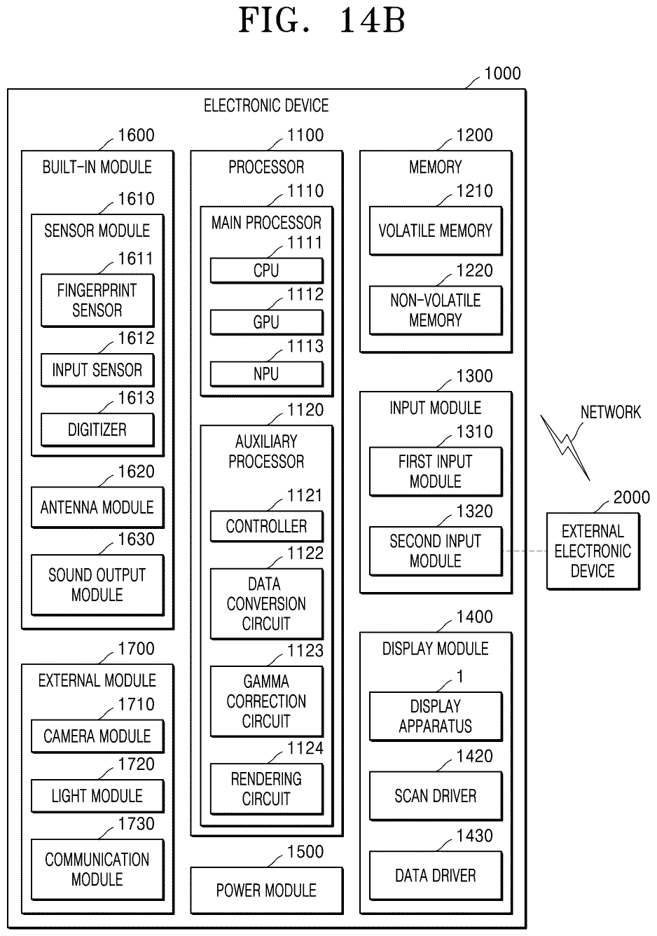

FIG. 14A is a perspective view schematically illustrating the electronic device 1000 including a display apparatus according to an embodiment of the present disclosure, and FIG. 14B is a block diagram schematically illustrating the electronic device 1000 including the display apparatus 1 according to an embodiment of the present disclosure.

Referring to FIG. 14A, the electronic device 1000 may be freely and three-dimensionally deformed and may provide a three-dimensional image surface via the display area DA. The free and three-dimensional deformation of the electronic device 1000 is distinguished from an operation of an electronic device having a rollable display apparatus, such as, for example, a case where a portion of a rolled-up display area is visible to a user and then another portion of the rolled-up display area is unfolded until the entire display area is visible to the user (or a case where the entire unfolded display area is visible to a user and then the display area is rolled up until a portion of the display area is visible to the user). The electronic device 1000 according to embodiments of the present disclosure may be deformed such that the area of the entire display area DA is increased or reduced again as the electronic device 1000 is deformed in the x direction, the y direction, and/or the z direction.

Referring to FIG. 14B, the electronic device 1000 may include a processor 1100, a memory 1200, an input module 1300, a display module 1400, a power module 1500, a built-in module 1600, and an external module 1700. According to an embodiment, the electronic device 1000 may not include at least one of the above-described components or may further include one or more other components. According to an embodiment, some components (for example, the built-in module 1600) among the above-described components may be integrated into another component (for example, the display module 1400).

The processor 1100 may execute software to control at least one other component (for example, hardware or software component) of the electronic device 1000, which is connected to the processor 1100, and may perform various data processing or computation. According to an embodiment, as at least part of data processing or computation, the processor 1100 may store, in a volatile memory 1210, a command or data received from another component (for example, the input module 1300, a sensor module 1610, or a communication module 1730) or process the command or data stored in the volatile memory 1210, and the result data may be stored in a non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU 1113 is a processor specialized in processing artificial intelligence models, and artificial intelligence models may be created via machine learning. An artificial intelligence model may include a plurality of artificial neural network layers. An artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or one of a combination of two or more thereof, but is not limited to the above-described example. The artificial intelligence model may further or alternatively include a software structure, in addition to a hardware structure. At least two of the processing units and the processor described herein may be implemented as a single integrated configuration (for example, a single chip) or may each be implemented as an independent configuration (for example, a plurality of chips).

The auxiliary processor 1120 may include a controller 1121. The controller 1121 may include an interface conversion circuit and a timing control circuit. The controller 1121 receives an image signal from the main processor 1110, converts a data format of the image signal to match interface specifications with the display module 1400, and outputs image data. The controller 1121 may output various control signals for driving the display module 1400.

The auxiliary processor 1120 may further include a data processing circuit such as, for example, a data conversion circuit 1122, a gamma correction circuit 1123, a rendering circuit 1124, or the like. The data conversion circuit 1122 may receive image data from the controller 1121 and convert the image data to compensate for the image data to display an image with a desired luminance according to characteristics of the electronic device 1000 or user settings, or to reduce power consumption or compensate for image retention. The gamma correction circuit 1123 may convert image data or a gamma reference voltage to ensure that an image displayed on the electronic device 1000 has desired gamma characteristics. The rendering circuit 1124 may receive image data from the controller 1121 and render the image data in consideration of a pixel arrangement of the display apparatus 1 applied to the electronic device 1000. At least one of the data conversion circuit 1122, the gamma correction circuit 1123, and the rendering circuit 1124 may be integrated into another component (for example, the main processor 1110 or the controller 1121). In an embodiment, the auxiliary processor 1120 may be integrated into a data driver 1430.

The memory 1200 may store various data used by at least one component (for example, the processor 1100 or the sensor module 1610) of the electronic device 1000, and input data or output data for commands related thereto. The memory 1200 may include at least one of the volatile memory 1210 and the non-volatile memory 1220.

The input module 1300 may receive, from the outside of the electronic device 1000 (for example, a user or an external electronic apparatus 2000), a command or data to be used in a component (for example, the processor 1100, the sensor module 1610, or a sound output module 1630) of the electronic device 1000.

The input module 1300 may include a first input module 1310 to which a command or data is input from a user, and a second input module 1320 to which a command or data is input from the external electronic apparatus 2000.

The first input module 1310 may include a microphone, a mouse, a keyboard, or a pen (for example, a passive pen or an active pen). The first input module 1310 may include a mechanical input means, such as, for example, a button, a dome switch, a jog wheel, a jog switch, or the like, which is arranged on a rear or side surface of the electronic device 1000, or a touch input means. The touch input means may include a touch screen layer of the display apparatus 1.

The second input module 1320 may connect the electronic device 1000 to various types of external electronic apparatuses 2000 in a wired or wireless manner. According to an embodiment, the second input module 1320 may include a high definition multimedia interface (HDMI), a universal serial bus (USB) interface, an SD card interface, or an audio interface. The second input module 1320 may include a connector, for example, an HDMI connector, a USB connector, an SD card connector, or an audio connector (for example, a headphone connector), which may physically connect the electronic device 1000 to the external electronic apparatus 2000. The electronic device 1000 may perform appropriate control related to the connected external electronic apparatus 2000 in response to the external electronic apparatus 2000 being connected to the second input module 1320.

The display module 1400 provides information visually to a user. The display module 1400 may include the display apparatus 1, a scan driver 1420, and the data driver 1430.

The display apparatus 1 displays (outputs) information processed by the electronic device 1000. The display apparatus 1 may display execution screen information of an application running on the electronic device 1000, or may display user interface (UI) or graphical user interface (GUI) information in accordance with the execution screen information.

The scan driver 1420, as a driving chip, may be mounted on the display apparatus 1. Alternatively, the scan driver 1420 may be directly formed on the display apparatus 1. For example, the scan driver 1420 may include an amorphous silicon TFT gate driver circuit (ASG), a low temperature polycrystalline silicon (LTPS) TFT gate driver circuit, or an oxide semiconductor TFT gate driver circuit (OSG), which is embedded in the display apparatus 1. The scan driver 1420 receives a control signal from the controller 1121 and outputs scan signals to the display apparatus 1 in response to the control signal.

The display apparatus 1 may further include an emission control driver. The emission control driver outputs an emission control signal to the display apparatus 1 in response to the control signal received from the controller 1121. The emission control driver may be formed separately from the scan driver 1420 or may be integrated into the scan driver 1420.

The data driver 1430 receives a control signal from the controller 1121, converts image data into a data voltage in the form of an analog voltage in response to the control signal, and then outputs data voltages to the display apparatus 1.

The data driver 1430 may be integrated into some components of the auxiliary processor 1120. For example, the data driver 1430 may be provided as a timing controller embedded driver integrated circuit (IC) including the controller 1121.

The power module 1500 supplies power to a component of the electronic device 1000. The power module 1500 may include a battery that is charged with a power voltage. In some aspects, the power module 1500 includes a connection port, and the connection port may be included in the second input module 1320 to which an external charger that supplies power to charge the battery is connected. Alternatively, the power module 1500 may include a wireless power transmission/reception member to enable wireless charging of the battery. The wireless power transmission/reception member may include a plurality of coil-shaped antenna radiators. The power module 1500 may include a power management integrated circuit (PMIC). The PMIC supplies optimized power to each of the components of the electronic device 1000.

The electronic device 1000 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touch screen layer of the display apparatus 1 and a touch sensor driving unit. The sensor module 1610 may detect an input from a user's body or an input from a pen and generate an electrical signal or data value corresponding to the input. The sensor module 1610 may include at least any one of a fingerprint sensor 1611, an input sensor 1612, a digitizer 1613, and a strain sensor 1614.

The fingerprint sensor 1611 may generate a data value corresponding to a user's fingerprint. The fingerprint sensor 1611 may include either an optical or capacitive fingerprint sensor.

The input sensor 1612 may generate a data value corresponding to coordinate information of an input from a user's body or an input from a pen. The input sensor 1612 generates, as the data value, the amount of change in capacitance due to the input. The input sensor 1612 may detect an input from a passive pen or may transmit/receive data to/from an active pen.

The input sensor 1612 may measure a biological signal such as, for example, blood a force, moisture, or body fat. In an example in which a part of a user's body is in contact with a sensor layer or a sensing panel and the user does not move for a certain period of time, the input sensor 1612 may detect a biological signal and output information desired by the user to the display module 1400, based on a change in electric field caused by the part of their body.

The digitizer 1613 may generate a data value corresponding to coordinate information of an input from a pen. The digitizer 1613 generates, as the data value, the amount of change in electromagnetic force due to the input. The digitizer 1613 may detect an input from a passive pen or may transmit/receive data to/from an active pen.

The strain sensor 1614 may include layers, patterns, or wirings, each having a measurable physical quantity that changes according to elongation of the display apparatus 1. For example, the strain sensor 1614 may include wirings having a resistance and/or capacitance that changes due to elongation of the display apparatus 1. In another embodiment, the strain sensor 1614 may include an optical layer or an optical pattern, each having a transmittance and/or reflectance that changes due to elongation of the display apparatus 1.

Based on the physical quantity that changes according to the elongation of the display apparatus 1, which is measured by the strain sensor 1614, the electronic device 1000 may improve the quality of an image implemented on the display apparatus 1 or control the display apparatus 1. The control operation of the display apparatus 1 may include an operation such as, for example, displaying an operation image for protecting the display apparatus 1, cutting off a voltage for driving the display apparatus 1, or stopping an elongation operation of the display apparatus 1.

In an embodiment, at least one of the fingerprint sensor 1611, the input sensor 1612, the digitizer 1613, and the strain sensor 1614 may be embedded in the display apparatus 1. For example, at least one of the fingerprint sensor 1611, the input sensor 1612, the digitizer 1613, and the strain sensor 1614 may be formed via a process that continues from a process for forming pixel circuits and light-emitting diodes of the display apparatus 1. Accordingly, the display apparatus 1 may function as one of the input modules 1300 that provide an input interface between the electronic device 1000 and a user, and may function as the display module 1400 that provides an output interface between the electronic device 1000 and the user.

In an embodiment, at least two of the fingerprint sensor 1611, the input sensor 1612, the digitizer 1613, and the strain sensor 1614 may be formed to be integrated into single sensing panel via the same process. In an embodiment, the sensing panel may be arranged between the display apparatus 1 and a window arranged on an upper side of the display apparatus 1, but embodiments of the present disclosure are not limited thereto.

The antenna module 1620 may include at least one antenna for transmitting or receiving a signal or power to or from the outside. According to an embodiment, the communication module 1730 may transmit or receive a signal to or from an external electronic apparatus via an antenna suitable for a communication method. An antenna pattern of the antenna module 1620 may be integrated into one component (for example, the display apparatus 1) of the display module 1400 or the input sensor 1612.

The sound output module 1630, as an apparatus for outputting a sound signal to the outside of the electronic device 1000, may output sound data received from the communication module 1730 or stored in the memory 1200, in a call signal reception mode, a call mode, a recording mode, a voice recognition mode, or a broadcast reception mode. The sound output module 1630 may output a sound signal related to a function (for example, a call signal reception sound, a message reception sound, or the like) performed by the electronic device 1000. The sound output module 1630 may include a receiver and a speaker. At least one of the receiver and the speaker may be a sound generating apparatus which is attached to a lower portion of the display apparatus 1 and vibrates the display apparatus 1 to output sound. The sound generating apparatus may be a piezoelectric element or piezoelectric actuator that contracts and expands according to an electric signal, or may be an exciter that generates a magnetic force by using a voice coil to vibrate the display apparatus 1.

The camera module 1710 may capture a still image and a moving image. According to an embodiment, the camera module 1710 may include one or more lenses, an image sensor, or an image signal processor. The camera module 1710 may further include an infrared camera capable of measuring the presence of a user, the user's location, the user's line of sight, or the like.

The light module 1720 may output a signal for notifying an event occurrence by using light from a light source, or may provide light for obtaining an image. Herein, examples of the event occurrence may include receiving a message, receiving a call signal, a missed call, an alarm, a schedule notification, receiving an email, a battery charging capacity notification, or the like. The light module 1720 may include a light-emitting diode or a xenon lamp. The light module 1720 may emit monochromatic or multi-colored light from a front or rear surface of the electronic device 1000. The light module 1720 may operate in conjunction with the camera module 1710 or may operate independently.

The communication module 1730 may support establishment of a wired or wireless communication channel between the electronic device 1000 and the external electronic apparatus 2000, and communication via the established communication channel. The communication module 1730 may include one or both of a wireless communication module, such as, for example, a cellular communication module, a short-range wireless communication module, or a global navigation satellite system (GNSS), and a wired communication module, such as, for example, a local area network (LAN) communication module or a power line communication module. The communication module 1730 may transmit/receive a wireless signal to/from an Internet network, by using at least one of wireless LAN (WLAN), wireless-fidelity (Wi-Fi), Wi-Fi direct, and digital living network alliance (DLNA) technologies. In some aspects, the communication module 1730 may support a short-range communication, by using at least one of Bluetooth™, radio frequency identification (RFID), infrared data association (IrDA), ultra wideband (UWB), ZigBee, near-field communication (NFC), Wi-Fi, Wi-Fi direction, wireless USB technologies. The various types of the communication module 1730 may be implemented as a single chip or may each be implemented as a separate chip.

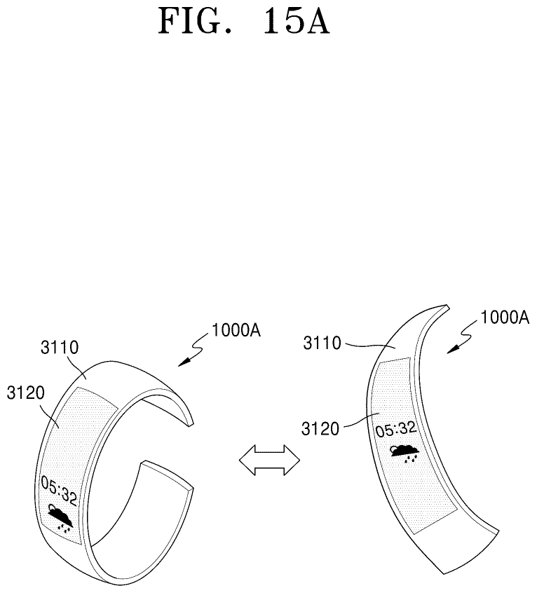

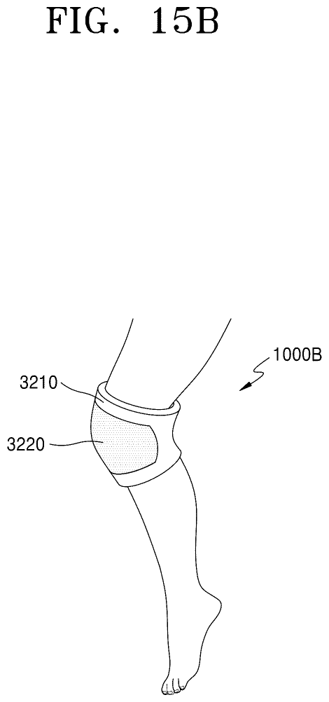

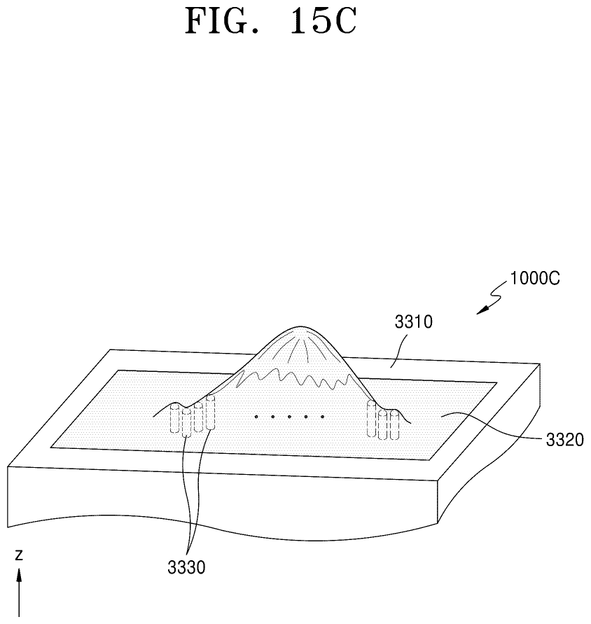

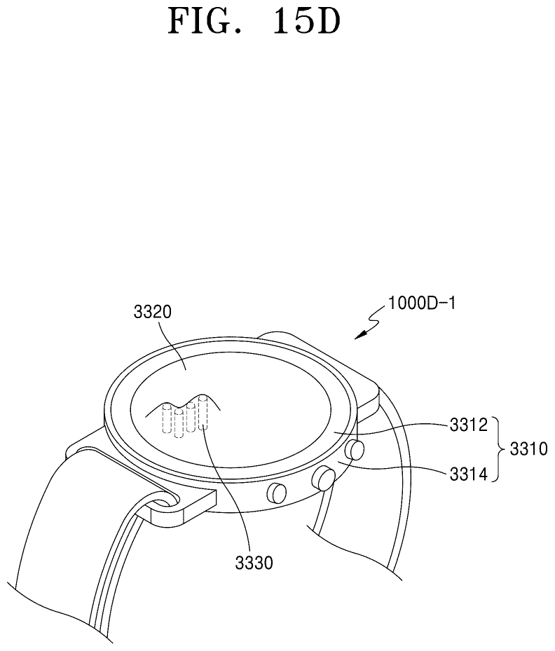

FIGS. 15A to 15D are each a perspective view schematically illustrating embodiments of an electronic device including a display apparatus according to an embodiment of the present disclosure.

Referring to FIG. 15A, the display apparatus according to an embodiment of the present disclosure may be utilized in a wearable electronic device 1000A that may be worn on a part of a user's body. The wearable electronic device 1000A may include a body portion 3110 and a display portion 3120 provided on the body portion 3110. The display apparatus according to embodiments of the present disclosure may be used as the display portion 3120 of the wearable electronic device 1000A. As illustrated in FIG. 15A, the wearable electronic device 1000A may be deformable. In an embodiment, it may be used as a smart watch or a smartphone, depending on a user's choice.

FIG. 15B illustrates a medical electronic device 1000B. In an embodiment, the medical electronic device 1000B may include a body portion 3210 and a light-emitting portion 3220. The display apparatus according to embodiments of the present disclosure may be used as the light-emitting portion 3220 of the medical electronic device 1000B. The light-emitting portion 3220 may emit light (for example, infrared light, visible light, or the like) in a certain wavelength band to a patient's body. In an embodiment, the body portion 3210 may have a stretchable fiber material and may have a structure that may be worn on a user's body.

FIG. 15C illustrates an educational electronic device 1000C. In an embodiment, the educational electronic device 1000C may include a display portion 3320 provided within a frame 3310. The display apparatus according to embodiments of the present disclosure may be used as the display portion 3320. An image such as, for example, waves crashing on the sea, snow-covered mountains, or flowing lava from a volcano may be provided via the display portion 3320, and in this case, the display portion 3320 may be stretched in a height direction (for example, the z direction) by reflecting the height of the waves, mountains, or lava. In some embodiments, a portion of the display portion 3320 may show movement of lava in three dimensions by sequentially changing the height in a direction in which the lava flows. The educational electronic device 1000C may include a plurality of pins (or stroke units) 3330 arranged on a back surface of the display portion 3320 such that the display portion 3320 is stretched in the height direction. The pins 3330 may move in the third direction (for example, the z direction or the −z direction), allowing an image displayed on the display portion 3320 to have a three-dimensional height. FIG. 15C illustrates the educational electronic device 1000C, but its use is not limited as long as it provides certain image information.

FIG. 15D illustrates that a display apparatus is used in a wearable electronic device 1000D-1 such as, for example, a smart watch. In an embodiment, the display apparatus corresponding to a display portion 3320 of the electronic device 1000D-1 is capable of three-dimensional elongation and thus may provide various haptic information to a user. In an embodiment, the electronic device 1000D-1 may provide haptic information, such as, for example, Braille display for the visually impaired or tactile stimulation linked to an image, by using the plurality of pins (stroke units) 3330 arranged under the display portion 3320. The display apparatus forming the display portion 3320 is capable of three-dimensional elongation and thus may provide the above-described haptic information to a user.

The embodiments described with reference to FIGS. 15A to 15D illustrate the electronic devices 1000A, 1000B, 1000C, and 1000D-1 in which the display portion may be three-dimensionally deformed, but embodiments of the present disclosure are not limited thereto. As in embodiments described herein, the display apparatus according to embodiments of the present disclosure may be used in an electronic device in which the shape of a portion (for example, a screen) capable of displaying an image is fixed.

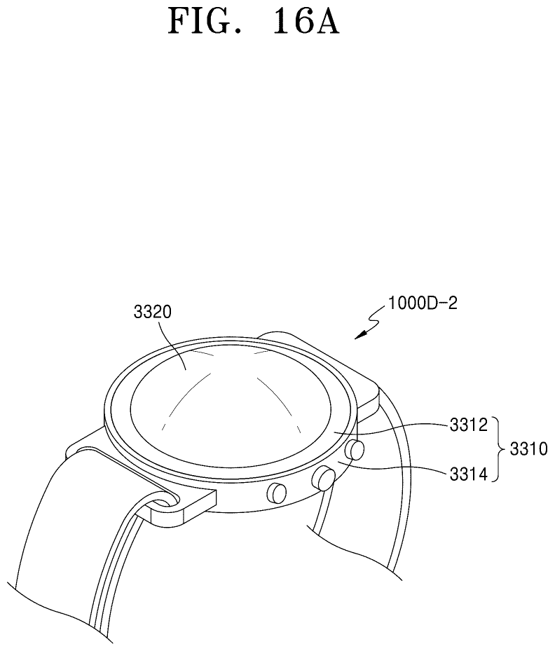

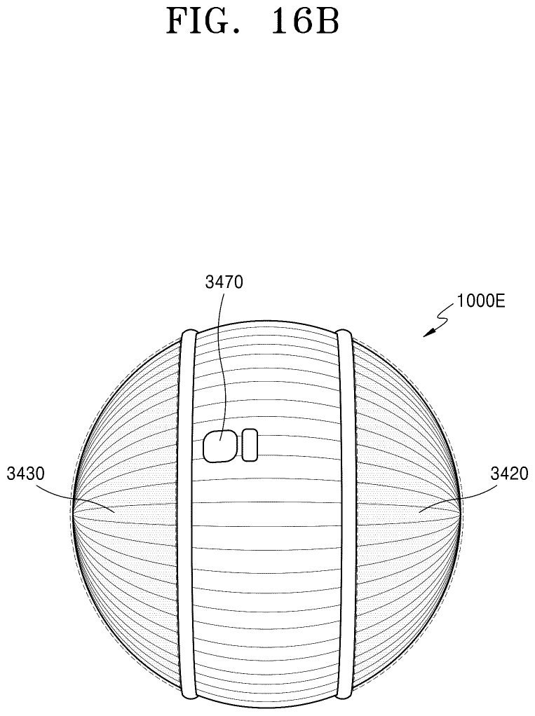

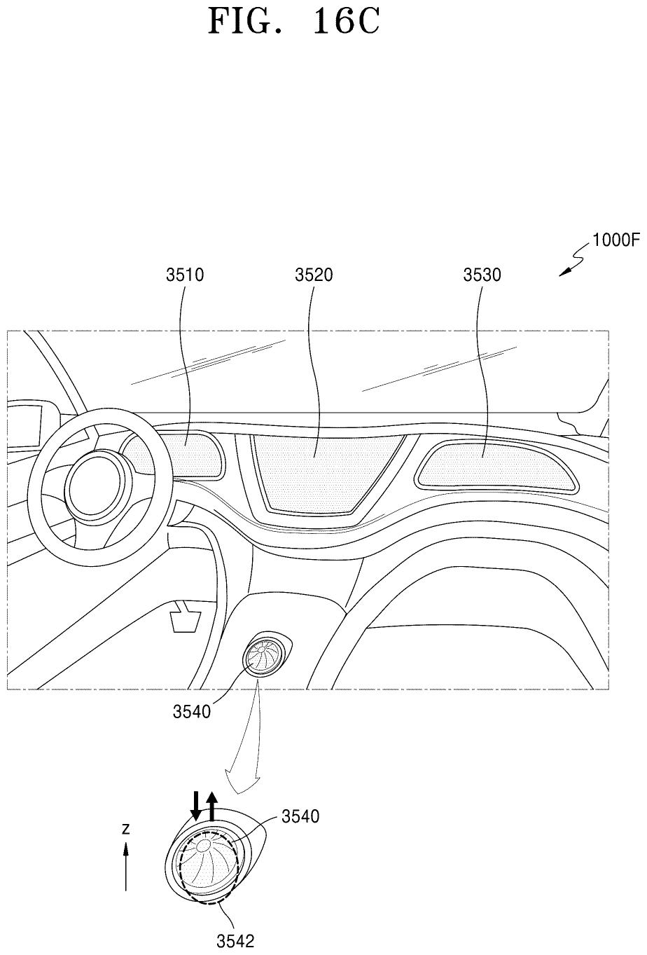

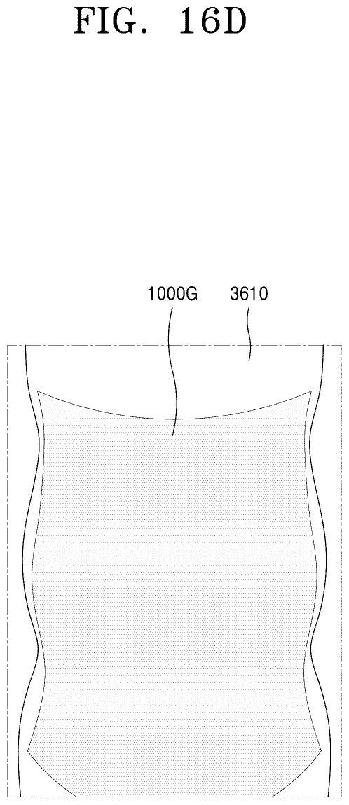

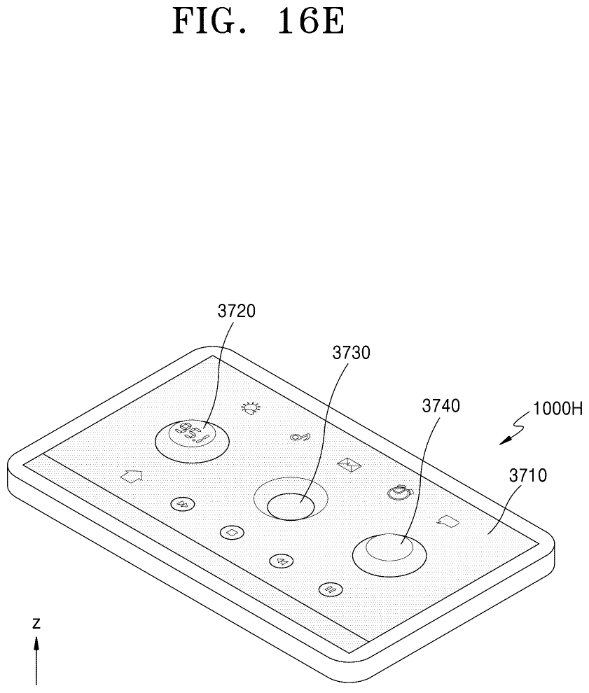

FIGS. 16A to 16E are each a perspective view schematically illustrating an electronic device according to an embodiment of the present disclosure.

FIG. 16A illustrates that a display apparatus is used in a wearable electronic device 1000D-2 such as, for example, a smart watch. The electronic device 1000D-2 illustrated in FIG. 16A may include the display portion 3320, wherein the display portion 3320 may have a three-dimensional dome shape (or hemispherical shape). In a process of manufacturing the electronic device 1000D-2, a display apparatus may be assembled onto a dome-shaped body frame, and in this case, the display apparatus is capable of three-dimensional elongation and thus may be assembled in an elongated state along the shape of the hemispherical body frame.

FIG. 16B illustrates that an electronic device 1000E according to an embodiment of the present disclosure includes a robot. The robot may recognize movement or objects by using the camera module 1710 and may display a certain image to a user via display portions 3420 and 3430. In some embodiments, the display apparatuses according to an embodiment of the present disclosure may be stretched in various direction as described herein and thus may be assembled onto a body frame having a hemispherical shape, and thus, the robot may include the hemispherical display portions 3420 and 3430.

FIG. 16C illustrates a vehicle display device 1000F as an electronic device, according to an embodiment of the present disclosure. The vehicle display device 1000F may include a cluster 3510, a center information display (CID) 3520, and/or a co-driver display 3530. The display apparatus according to an embodiment of the present disclosure may be stretched in various directions and thus may be used in the cluster 3510, the CID 3520, and/or the co-driver display 3530 without being constrained by the shape of a vehicle's internal frame.

FIG. 16C illustrates that the cluster 3510, the CID 3520, and/or the co-driver display 3530 are separated from each other, but embodiments of the present disclosure are not limited thereto. In another embodiment, two or more selected from the cluster 3510, the CID 3520, and the co-driver display 3530 may be integrally connected.

In some embodiments, the vehicle display device 1000F may include a button 3540 capable of displaying a certain image. Referring to an enlarged view of FIG. 16C, the hemispherical button 3540 may include an object 3542, which provides the sensation of using the button 3540 while moving in the z direction or the −z direction, and a display apparatus arranged above the object 3542. In some embodiments, when the object 3542 has a three-dimensionally rounded surface, the display apparatus may also have a three-dimensionally rounded surface.

FIG. 16D illustrates that the electronic device according to an embodiment is an electronic device 1000G used for advertisement or exhibition. In some embodiments, the electronic device 1000G used for advertisement or exhibition may be installed on a fixed structure 3610, such as, for example, a wall or a pillar. In an example in which the structure 3610 includes an uneven surface as illustrated in FIG. 16D, the electronic device 1000G used for advertisement or exhibition may also be arranged along the uneven surface of the structure 3610. In some embodiments, the electronic device 1000G used for advertisement or exhibition may be installed on the structure 3610 by using a heat shrink film, or the like.

FIG. 16E illustrates that an electronic device 1000H according to an embodiment of the present disclosure is a controller. The controller may include an image-type button. For example, the controller may include a first button area 3720, a second button area 3730, and a third button area 3740 in which a partial area of a display portion 3710 protrudes in the z direction or in the −z direction (or is recessed in the z direction). In some embodiments, the first button area 3720 and the third button area 3740 may protrude in the z direction, and the second button area 3730 may protrude in the −z direction (or may be recessed in the z direction).

As such, the present disclosure has been described with reference to an embodiment illustrated in the drawings, but this is an example, and those of ordinary skill in the art will understand that various modifications and variations of the embodiment are possible therefrom. Therefore, the true technical protection scope of the present disclosure should be determined by the technical idea of the appended claims.

What is claimed is:

1. An electronic device comprising:
a display apparatus which is stretchable; and
a pressing unit that is fixed to the display apparatus and applies a force to the display apparatus, wherein:
the pressing unit comprises:
a frame portion;
a plate portion arranged on the frame portion and having magnetism; and
a stroke module arranged between the frame portion and the plate portion and which moves in a first direction and a second direction crossing the first direction with respect to the frame portion, and
the stroke module comprises a stroke unit which is switched between a first state with magnetism and a second state with no magnetism and moves in a third-1 direction toward the plate portion and a third-2 direction away from the plate portion.

2. The electronic device of claim 1, wherein the stroke unit applies the force to the plate portion in the first state.

3. The electronic device of claim 2, wherein:
the stroke unit applies the force to the plate portion in the third-1 direction, and
at least a portion of the display apparatus is elongated in the third-1 direction based on the force.

4. The electronic device of claim 2, wherein:
the stroke unit applies the force to the plate portion in the third-2 direction, and
at least a portion of the display apparatus is elongated in the third-2 direction based on the force.

5. The electronic device of claim 2, wherein the stroke unit is switched from the first state to the second state and moves in the third-2 direction such that the stroke unit is spaced apart from the plate portion.

6. The electronic device of claim 1, wherein the stroke unit comprises:
a body portion; and
a roller portion connected to the body portion in the third-1 direction and which freely rotates with respect to the body portion.

7. The electronic device of claim 6, wherein, in a state where the pressing unit applies the force to the display apparatus, the stroke module moves in at least one of the first direction and the second direction with respect to the frame portion, such that the roller portion rotates.

8. The electronic device of claim 1, wherein:
the stroke module is provided as a plurality of stroke modules, and
the plurality of stroke modules move independently from one another.

9. The electronic device of claim 8, wherein the plurality of stroke modules apply respective forces to the plate portion at different respective positions of the plate portion.

10. The electronic device of claim 1, wherein the stroke unit comprises at least one of an electromagnet and an electropermanent magnet.

11. An electronic device comprising:
a display apparatus which is stretchable; and
a pressing unit that is fixed to the display apparatus and applies a force to the display apparatus, wherein:
the pressing unit comprises:
a frame portion;
a plate portion arranged on the frame portion and having magnetism; and
a stroke module that is arranged between the frame portion and the plate portion, moves in a first direction and a second direction crossing the first direction with respect to the frame portion, and applies a force to the plate portion, and
the plate portion comprises a first area and a plurality of second areas having elongations different from an elongation of the first area.

12. The electronic device of claim 11, wherein the stroke module comprises a stroke unit which is switched between a first state with magnetism and a second state with no magnetism and moves in a third-1 direction toward the plate portion and a third-2 direction away from the plate portion.

13. The electronic device of claim 12, wherein the stroke unit applies the force to the plate portion in the first state, at a position where the stroke module overlaps any one of the plurality of second areas.

14. The electronic device of claim 13, wherein:
the stroke unit applies the force to the plate portion in the third-1 direction, and
at least a portion of the display apparatus is elongated in the third-1 direction based on the force.

15. The electronic device of claim 13, wherein:
the stroke unit applies the force to the plate portion in the third-2 direction, and
at least a portion of the display apparatus is elongated in the third-2 direction based on the force.

16. The electronic device of claim 13, wherein the stroke unit is switched from the first state to the second state and moves in the third-2 direction such that the stroke unit is spaced apart from the plate portion.

17. The electronic device of claim 12, wherein the stroke unit comprises:
a body portion; and
a roller portion connected to the body portion in the third-1 direction and which freely rotates with respect to the body portion.

18. The electronic device of claim 17, wherein, in a state where the pressing unit applies the force to the display apparatus, the stroke module moves in at least one of the first direction and the second direction with respect to the frame portion, such that the roller portion rotates.

19. The electronic device of claim 12, wherein the stroke unit comprises at least one of an electromagnet and an electropermanent magnet.

20. The electronic device of claim 11, wherein:
the stroke module is provided as a plurality of stroke modules, and
the plurality of stroke modules move independently from one another and apply respective forces to the plate portion at different respective positions of the plate portion.
